(19) United States
(12) Patent Application Publication
(10) Pub. No.: US 2026/0271457 A1
(43) Pub. Date: Sep. 10, 2026

(54) DISPLAY DEVICE, ELECTRONIC DEVICE AND METHOD FOR MANUFACTURING DISPLAY DEVICE

(71) Applicant: Samsung Display Co., LTD., Yongin-si (KR)

(72) Inventors: Young Kyo SEO, Yongin-si (KR); Gwang Geun LEE, Yongin-si (KR); Sun PARK, Yongin-si (KR); Young Seok SEO, Yongin-si (KR); Ki Chang EOM, Yongin-si (KR)

(21) Appl. No.: 19/441,588

(22) Filed: Jan. 6, 2026

(30) Foreign Application Priority Data
Mar. 6, 2025 (KR) 10-2025-0028984
May 13, 2025 (KR) 10-2025-0061787

(51) Int. Cl. H10H 29/49; H10H 29/01; H10H 29/37; H10H 29/80

(52) U.S. Cl. CPC H10H 29/49; H10H 29/012; H10H 29/37; H10H 29/8321; H10H 29/8323

(57) ABSTRACT

A display device according to one or more embodiments includes a substrate, pixel electrodes and electrode lines spaced apart from each other on the substrate, light emitting elements arranged on the pixel electrodes, and electrode patterns arranged on the light emitting elements and intersecting the electrode lines, wherein the electrode lines and the electrode patterns extend in different directions and are electrically connected to each other to form a mesh-shaped common electrode.

### CROSS-REFERENCE TO RELATED APPLICATION

The present application claims priority to and the benefit of Korean Patent Application No. 10-2025-0028984 filed on Mar. 6, 2025, and from Korean Patent Application No. 10-2025-0061787 filed on May 13, 2025, in the Korean Intellectual Property Office, the disclosure of each of which in its entirety is incorporated herein by reference.

### BACKGROUND

### 1. Field

One or more aspects of embodiments of the present disclosure are directed to a display device, an electronic device and a method for manufacturing the display device.

### 2. Description of the Related Art

As the creation, distribution and manipulation of information gain economic, cultural and social importance in our society, various types (kinds) of electronic devices and display devices capable of displaying images are being developed. A display device may be provided alone, or may be included in an electronic device and used as a display screen of the electronic device.

The display device and the electronic device may include pixels that emit light in response to driving signals. Each pixel may include a plurality of sub-pixels to emit light of one or more suitable colors including standard white. Some display devices and electronic devices may use a micro light emitting diode (Micro-LED) or another type or kind of light emitting element as a light source of the sub-pixel.

### SUMMARY

Aspects of embodiments of the present disclosure provide a display device and an electronic device capable of reducing a voltage drop of a driving voltage applied to light emitting elements, and a method for manufacturing the display device.

Aspects of embodiments of the present disclosure also provide a display device and an electronic device capable of easily or suitably repairing a defect caused by a defective light emitting element and increasing a manufacturing efficiency, and a method for manufacturing the display device.

However, aspects of the present disclosure are not restricted to the ones set forth herein. The above and other aspects of the present disclosure will become more apparent to one of ordinary skill in the art to which the present disclosure pertains by referencing the detailed description of the present disclosure given herein below.

According to one or more embodiments of the present disclosure, there is provided a display device including, a substrate, pixel electrodes and electrode lines spaced apart from each other on the substrate, light emitting elements arranged on the pixel electrodes, and electrode patterns arranged on the light emitting elements and intersecting the electrode lines, wherein the electrode lines and the electrode patterns extend in different directions and are electrically connected to each other to form a mesh-shaped common electrode.

In one or more embodiments, the electrode patterns may contain a transparent conductive material, and the electrode lines may contain a conductive material having a lower resistivity than the transparent conductive material of the electrode patterns.

In one or more embodiments, the pixel electrodes and the electrode lines may be located in a same layer and may contain a same material.

In one or more embodiments, the electrode patterns may each extend in a first direction and may be arranged in a second direction crossing the first direction.

In one or more embodiments, each of the electrode patterns may overlap a plurality of light emitting elements arranged in the first direction among the light emitting elements, and may include first portions respectively covering the plurality of light emitting elements and second portions connecting the first portions, and a width of the second portions may be less than a width of the first portions.

In one or more embodiments, a plurality of light emitting elements may be arranged on each of the pixel electrodes, and among the plurality of light emitting elements arranged on one of the pixel electrodes, a first light emitting element may be isolated from the common electrode, and a second light emitting element may be electrically connected to the (mesh-shaped) common electrode.

In one or more embodiments, the electrode pattern located on the first light emitting element may be disconnected at second portions located around the first light emitting element and isolated from the (mesh-shaped) common electrode.

In one or more embodiments, the electrode lines may each extend in the second direction and may be arranged in the first direction.

In one or more embodiments, the pixel electrodes may be arranged in the first direction and the second direction, and the pixel electrodes and the electrode lines may be arranged alternately with each other in the first direction.

In one or more embodiments, each of the light emitting elements may include, a first semiconductor layer located on one of the pixel electrodes and electrically connected to the one pixel electrode, an active layer located on the first semiconductor layer, and a second semiconductor layer located on the active layer and electrically connected to the (mesh-shaped) common electrode.

In one or more embodiments, the display device may further include an insulating layer located between the pixel electrodes and the electrode patterns and around (e.g., surrounding) the light emitting elements.

In one or more embodiments, the insulating layer may expose a part of the electrode lines at a portion where the electrode lines and the electrode patterns intersect each other, and may cover another part of the electrode lines, and at a portion where the electrode lines are exposed, the electrode lines and the electrode patterns may be in contact with each other.

In one or more embodiments, the insulating layer may include island-shaped insulating patterns which are individually located in respective sub-pixels including the respective pixel electrodes and are separated from each other.

In one or more embodiments, the pixel electrodes and the electrode lines may be arranged alternately with each other in a first direction, and the insulating layer may include insulating patterns which are separated from each other in the first direction and each extend in a second direction crossing the first direction.

In one or more embodiments, the display device may further include a bank around (e.g., which surrounds) the light emitting elements at a position spaced apart from the light emitting elements and overlaps the electrode lines, and the bank may fill a groove formed in a portion where the insulating layer is removed.

According to one or more embodiments of the present disclosure, there is provided an electronic device including a display module including a display panel, and a processor to transmit an image data signal to the display module. The display panel may include a substrate, pixel electrodes and electrode lines spaced apart from each other on the substrate, light emitting elements arranged on the pixel electrodes, and electrode patterns arranged on the light emitting elements and intersecting the electrode lines, wherein the electrode lines and the electrode patterns extend in different directions and may be electrically connected to each other to form a mesh-shaped common electrode.

In one or more embodiments, the electrode patterns may contain a transparent conductive material, and the electrode lines may contain a conductive material having a lower resistivity than the transparent conductive material of the electrode patterns.

In one or more embodiments, the electrode patterns may each extend in a first direction and may be arranged in a second direction crossing the first direction, and each of the electrode patterns may overlap a plurality of light emitting elements arranged in the first direction among the light emitting elements, and may include first portions respectively covering the plurality of light emitting elements and second portions connecting the first portions and having a width less than a width of the first portions.

According to one or more embodiments of the present disclosure, there is provided a method for manufacturing a display device, including, preparing a backplane substrate including a substrate and pixel electrodes and electrode lines spaced apart from each other on the substrate, arranging a plurality of light emitting elements on each of the pixel electrodes, forming an insulating layer around (e.g., surrounding) the light emitting elements and exposing a part of the electrode lines, forming electrode patterns on the electrode lines, the electrode patterns intersecting the electrode lines and being electrically connected to the electrode lines, the light emitting elements and the insulating layer, and performing defect inspection on the light emitting elements, wherein if a defective light emitting element is detected in the defect inspection, the method further include electrically isolating the defective light emitting element.

In one or more embodiments, each of the electrode patterns may extend in a first direction and may include first portions covering respective light emitting elements arranged in the first direction among the light emitting elements, and second portions connecting the first portions and having a width less than a width of the first portions, and the electrically isolating of the defective light emitting element may include disconnecting the second portions of the electrode pattern located on the defective light emitting element around the defective light emitting element.

According to the display device and the electronic device, and the method for manufacturing the display device according to one or more embodiments, by forming a mesh-shaped common electrode including electrode lines including a low-resistance conductive material and electrode patterns that connect the electrode lines, the resistance of the common electrode may be lowered. Accordingly, the voltage drop of the driving voltage applied to the light emitting elements through the common electrode may be reduced, and the image quality of the display device and the electronic device may be improved.

In some embodiments, each sub-pixel may include a plurality of light emitting elements located on each pixel electrode. In one or more embodiments, the electrode patterns of the common electrode may be located on the light emitting elements of the sub-pixels and may have a narrow width around the light emitting elements. Accordingly, if (e.g., when) a defective light emitting element is detected, the defective light emitting element may be easily isolated from the common electrode, thereby repairing the defect caused by the defective light emitting element, and increasing the manufacturing efficiency of the display device and the electronic device.

However, effects according to the embodiments of the present disclosure are not limited to those exemplified above and one or more suitable other effects are incorporated herein.

### BRIEF DESCRIPTION OF THE DRAWINGS

The above and other aspects and features of the present disclosure will become more apparent by describing in more detail embodiments thereof with reference to the attached drawings, in which:

FIG. 1 is a perspective view illustrating a display device according to one or more embodiments;

FIG. 2 is a layout view illustrating a display device according to one or more embodiments;

FIG. 3 is a block diagram illustrating a display device according to one or more embodiments;

FIG. 4 is an equivalent circuit diagram illustrating a sub-pixel according to one or more embodiments;

FIG. 5 is a plan view illustrating a display area of a display panel according to one or more embodiments;

FIG. 6 is a plan view illustrating a display area of a display panel according to one or more embodiments;

FIG. 7 is a cross-sectional view illustrating a display area of a display panel according to one or more embodiments;

FIG. 8 is a cross-sectional view showing area A1 of FIG. 7 in more detail;

FIG. 9 is a cross-sectional view illustrating a display area of a display panel according to one or more embodiments;

FIG. 10 is a flowchart illustrating a method for manufacturing the display device according to one or more embodiments;

FIGS. 11-16 are cross-sectional views illustrating a method for manufacturing the display device according to one or more embodiments;

FIG. 17 is a plan view illustrating a display area of a display panel according to one or more embodiments;

FIG. 18 is a cross-sectional view illustrating a display area of a display panel according to one or more embodiments;

FIG. 19 is a block diagram of an electronic device according to one or more embodiments; and

FIG. 20 is schematic views of electronic devices according to one or more embodiments.

### DETAILED DESCRIPTION

The present disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when an element or a layer is referred to as being "on", “connected to”, or “coupled to” another element or layer, it can be directly on the other element or layer, or intervening layers may also be present. When an element is referred to as being “directly on," “directly connected to," or “directly coupled to” another element, there are no intervening elements present. The same reference numbers indicate the same components throughout the specification.

It will be understood that, although the terms "first," "second," and/or the like may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

As used herein, the singular forms “a,” “an,” and “the” are intended to include the plural forms as well, unless the context clearly indicates otherwise.

It will be further understood that the terms "includes," "including," “comprises,” and/or “comprising,” when used in this specification, specify the presence of stated features, steps, operations, elements, and/or components, but do not preclude the presence or addition of one or more other features, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the terms "use," "using," and "used" may be considered synonymous with the terms "utilize," "utilizing," and "utilized," respectively.

As used herein, expressions such as "at least one of", "one of", and "selected from", when preceding a list of elements, modify the entire list of elements and do not modify the individual elements of the list. For example, "at least one selected from among a, b and c", "at least one of a, b or c", and "at least one of a, b and/or c" may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure".

Spatially relative terms, such as “beneath,” “below,” “lower,” “above,” “upper,” "bottom," "top" and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or "over" the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms "substantially", "about", and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value.

Any numerical range recited herein is intended to include all sub-ranges of the same numerical precision subsumed within the recited range. For example, a range of "1.0 to 10.0" is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Features of each of the embodiments of the present disclosure may be partially or entirely combined with each other and may technically variously interwork with each other, and respective embodiments may be implemented independently of each other or may be implemented together in association with each other.

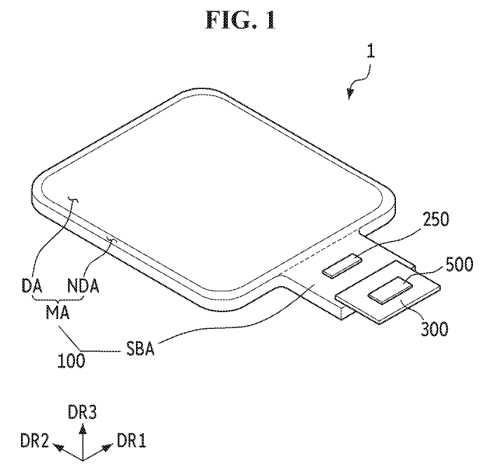

FIG. 1 is a perspective view illustrating a display device according to one or more embodiments.

Referring to FIG. 1, a display device 1 may be a device capable of providing an image, such as a moving image and/or a still image. For example, the display device 1 may be a device that includes a display module including a display panel 100 and thus may display an image. By way of example, the display device 1 may refer to any suitable electronic device that provides a display screen on which an image may be displayed and/or includes a display module for displaying an image.

The display device 1 may be provided alone, or may be included in an electronic device providing a display screen to form the display screen of the electronic device. For example, the display device 1 may be included in one or more suitable electronic devices such as televisions, laptop computers, monitors, billboards and/or the Internet of Things (IOT) as well as portable electronic devices such as mobile phones, smart phones, tablet personal computers (tablet PCs), smart watches, watch phones, mobile communication terminals, electronic notebooks, electronic books, portable multimedia players (PMPs), navigation systems and/or ultra mobile PCs (UMPCs), and/or used as a display screen. In one or more embodiments, the display device 1 may be included in other electronic devices such as a virtual reality (VR) device, an augmented reality (AR) device, and/or the like and used to display an image in the electronic device. In one or more embodiments, the electronic device including the display device 1 may further include a display device housing in which the display device 1 is accommodated and/or a case or cover for protecting the display device 1.

In FIG. 1, a display module, which is a main component of the display device 1, is illustrated. In one or more embodiments, the display device 1 (and/or an electronic device including a display module) may further include an additional component. For example, the display device 1 may further include a housing that accommodates the display module of FIG. 1.

In one or more embodiments, the display device 1 may be a light emitting display device such as an organic light emitting display using an organic light emitting diode, a quantum dot light emitting display including a quantum dot light emitting layer, an inorganic light emitting display including an inorganic semiconductor, and/or an ultra-small light emitting display using an ultra-small light emitting diode (for example, a micro light emitting diode (micro LED) and/or a nano light emitting diode (nano LED)). Hereinafter, as an example of the display device 1 to which embodiments may be applied, a light emitting display device including a micro or nano light emitting diode will be disclosed. However, the type or kind of light emitting element included in the display device 1 is not limited to an ultra-small light emitting diode, and the display device 1 may include light emitting elements of other types (kinds) and/or sizes.

The display device 1 may include a display panel 100, a display driving circuit 250, a circuit board 300, and a power supply unit 500 (also referred to as "power supply circuit").

The display panel 100 may, in plan view, be formed in a rectangular shape having short sides in a first direction DR1 and long sides in a second direction DR2 crossing the first direction DR1. The corner where the sides in the first direction DR1 and the sides in the second direction DR2 meet may be formed in a rounded or angled shape. The planar shape of the display panel 100 is not limited to the rectangular shape, and may be formed in another polygonal shape, a circular shape and/or an elliptical shape. The display panel 100 may be formed to be substantially flat, but the present disclosure is not limited thereto. The display panel 100 may be formed to be rigid as a whole, or may be formed to be flexible so that it can be curved, warped, bent, folded, and/or rolled in at least one part thereof.

The display panel 100 may include a main region MA and a sub-region SBA.

The main region MA may include the display area DA displaying an image and the non-display area NDA that is a peripheral area of the display area DA. The display area DA may include pixels for displaying an image. Each of the pixels may include a plurality of sub-pixels. For example, each of the pixels may include a first sub-pixel that is to emit light of a first color, a second sub-pixel that is to emit light of a second color, and a third sub-pixel that is to emit light of a third color.

The sub-region SBA may protrude from one side of the main region MA in the second direction DR2. In FIG. 1, the sub-region SBA is illustrated as being unfolded, but the sub-region SBA may be bent. When the sub-region SBA is bent, the main region MA and the sub-region SBA may overlap in a third direction DR3, which is the thickness direction of the display panel 100. The display driving circuit 250 may be arranged in the sub-region SBA.

The display driving circuit 250 may generate signals and voltages for driving the display panel 100. The display driving circuit 250 may be formed as an integrated circuit (IC) and attached onto the display panel 100 by a chip on glass (COG) method, a chip on plastic (COP) method, and/or an ultrasonic bonding method, but the present disclosure is not limited thereto. For example, the display driving circuit 250 may be attached onto the circuit board 300 by a chip on film (COF) method.

The circuit board 300 may be attached to one end of the sub-region SBA. In the case where the sub-region SBA is omitted, the circuit board 300 may be attached to one end of the main region MA (for example, one end of the non-display area NDA). Thus, the circuit board 300 may be electrically connected to the display panel 100 and the display driving circuit 250. The display panel 100 and the display driving circuit 250 may receive digital video data, timing signals, and/or driving voltages through the circuit board 300. The circuit board 300 may be a flexible printed circuit board, a printed circuit board, or a flexible film such as a chip on film.

The power supply unit 500 may generate a plurality of panel driving voltages according to a power voltage supplied from the outside. The power supply unit 500 may be formed as an integrated circuit (IC) and attached to the circuit board 300 by a COF method.

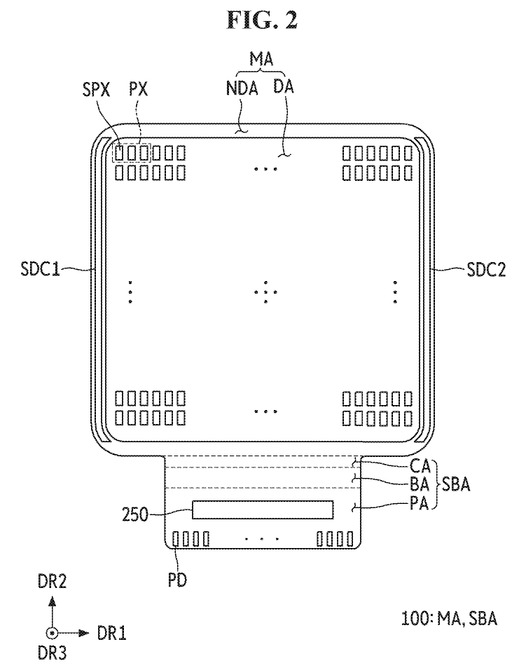

FIG. 2 is a layout view illustrating a display device according to one or more embodiments. It is shown by way of example in FIG. 2 that the sub-region SBA is unfolded without being bent.

Referring to FIG. 2, the display panel 100 may include the main region MA and the sub-region SBA.

The main region MA may include the display area DA to display an image and the non-display area NDA that is a peripheral area of the display area DA. The display area DA may occupy most of the main region MA. The display area DA may be located at the center of the main region MA.

The display area DA may include pixels PX for displaying an image, and each of the pixels PX may include a plurality of sub-pixels SPX. The pixel PX may be defined as a minimum unit sub-pixel group capable of expressing a white grayscale.

The non-display area NDA may be located adjacent to the display area DA. The non-display area NDA may be an area outside the display area DA. The non-display area NDA may surround the display area DA. The non-display area NDA may be an edge area of the display panel 100.

A first scan driver SDC1 and a second scan driver SDC2 may be located in the non-display area NDA. The first scan driver SDC1 may be located at one side (for example, left side) of the display panel 100, and the second scan driver SDC2 may be located at the other side (for example, right side) of the display panel 100, but the present disclosure is not limited thereto. Each of the first scan driver SDC1 and the second scan driver SDC2 may be electrically connected to the display driving circuit 250 through scan fan-out lines. Each of the first scan driver SDC1 and the second scan driver SDC2 may receive scan control signals inputted from the display driving circuit 250, generate scan signals in response to the scan control signals, and output the generated scan signals to scan lines.

The sub-region SBA may protrude from one side of the main region MA in the second direction DR2. The length of the sub-region SBA in the second direction DR2 may be less than the length of the main region MA in the second direction DR2. The length of the sub-region SBA in the first direction DR1 may be substantially equal to or less than the length of the main region MA in the first direction DR1. The sub-region SBA may be foldable to be located under the display panel 100. In this case, when the sub-region is folded, the sub-region SBA may overlap the main region MA in the third direction DR3.

The sub-region SBA may include a connection area CA, a pad area PA, and a bending area BA.

The connection area CA is an area protruding from one side of the main region MA in the second direction DR2. One side of the connection area CA may be in contact with the non-display area NDA of the main region MA, and the other side of the connection area CA may be in contact with the bending area BA.

The pad area PA is an area on which pads PD and the display driving circuit 250 are arranged. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is an area being bent or configured to be bent. When the bending area BA is bent, the pad area PA may be located under the connection area CA and the main region MA. The bending area BA may be located between the connection area CA and the pad area PA. One side of the bending area BA may be in contact with the connection area CA, and the other side of the bending area BA may be in contact with the pad area PA.

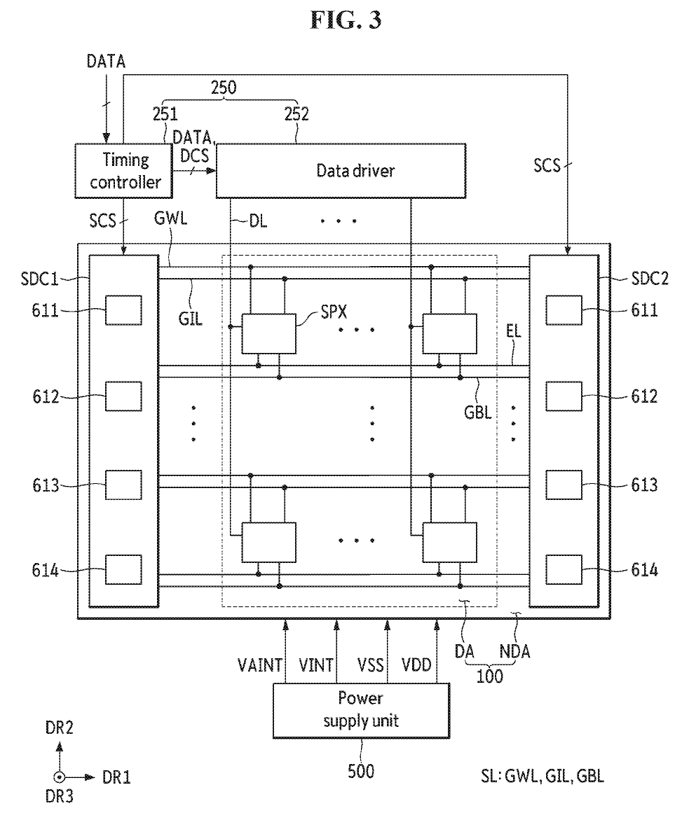

FIG. 3 is a block diagram illustrating a display device according to one or more embodiments.

Referring to FIG. 3 in addition to FIGS. 1 and 2, the display area DA may include pixels PX, scan lines SL, emission control lines EL, and data lines DL.

The pixels PX may be arranged in a matrix form and/or the like. For example, the pixels PX may be arranged in a matrix form in the first direction DR1 and the second direction DR2, but the present disclosure is not limited thereto. The scan lines SL and the emission control lines EL may extend in the first direction DR1 and be arranged in the second direction DR2. The data lines DL may extend in the second direction DR2 and may be arranged along the first direction DR1. In one or more embodiments, the scan lines SL may include write scan lines GWL, initialization scan lines GIL, and bias scan lines GBL.

Each of the plurality of sub-pixels SPX included in each of the pixels PX may be connected to any one write scan line GWL among the write scan lines GWL, any one initialization scan line GIL among the initialization scan lines GIL, any one bias scan line GBL among the bias scan lines GBL, any one emission control line EL among the emission control lines EL, and any one data line DL among the data lines DL. In describing the embodiments, the term "connection" may include direct connection or indirect connection, and may include electrical and/or physical connection. Each of the plurality of sub-pixels SPX may receive the data voltage of the data line DL according to the write scan signal of the write scan line GWL, and may cause a light emitting element to emit light according to the data voltage.

The non-display area NDA (or, for example, the non-display area NDA and the sub-region SBA) includes the first scan driver SDC1, the second scan driver SDC2, and the display driving circuit 250.

Each of the first scan driver SDC1 and the second scan driver SDC2 may include a write scan signal output unit 611, an initialization scan signal output unit 612, a bias scan signal output unit 613, and an emission control signal output unit 614. Each of the write scan signal output unit 611, the initialization scan signal output unit 612, the bias scan signal output unit 613, and the emission control signal output unit 614 may receive a scan timing control signal SCS from a timing controller 251 (also referred to as "timing control circuit").

The write scan signal output unit 611 may generate write scan signals according to the scan timing control signal SCS of the timing controller 251 and output them sequentially to the write scan lines GWL.

The initialization scan signal output unit 612 may generate initialization scan signals in response to the scan timing control signal SCS and sequentially output them to the initialization scan lines GIL.

The bias scan signal output unit 613 may generate bias scan signals according to the scan timing control signal SCS and output them sequentially to the bias scan lines GBL.

The emission control signal output unit 614 may generate emission control signals according to the scan timing control signal SCS and sequentially output them to the emission control lines EL.

The display driving circuit 250 includes the timing controller 251 and a data driver 252 (also referred to as "data driving circuit").

The data driver 252 may receive the digital video data DATA and the data timing control signal DCS from the timing controller 251. The data driver 252 converts the digital video data DATA into analog data voltages in response to the data timing control signal DCS, and outputs them to the data lines DL. In this case, the sub-pixels SPX may be selected by the write scan signal of the first scan driver SDC1 and the second scan driver SDC2, and data voltages may be supplied to the selected sub-pixels SPX.

The timing controller 251 may receive digital video data DATA and timing signals from the outside. The timing controller 251 may generate the scan timing control signal SCS and the data timing control signal DCS for controlling the display panel 100 in response to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate a plurality of panel driving voltages according to a power voltage supplied from the outside. For example, the power supply unit 500 may generate a first driving voltage VDD, a second driving voltage VSS, a third driving voltage VINT, and a fourth driving voltage VAINT and supply them to the display panel 100.

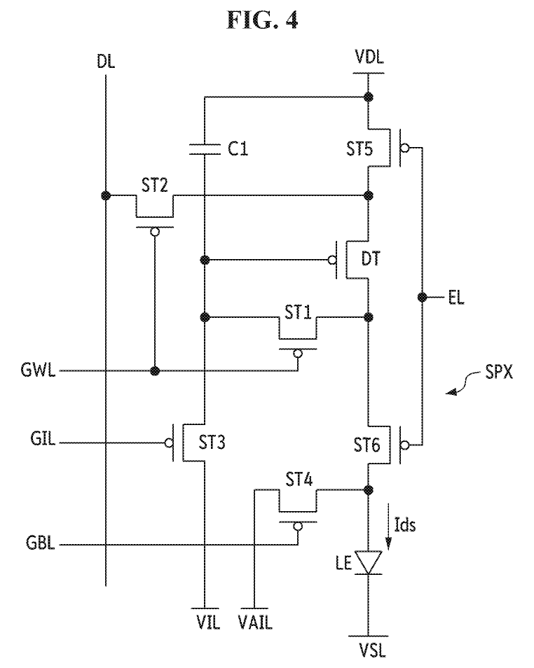

FIG. 4 is an equivalent circuit diagram illustrating a sub-pixel according to one or more embodiments.

Referring to FIG. 4, in addition to FIG. 3, the sub-pixel SPX according to one or more embodiments may be connected to the scan lines SL, the emission control line EL, and the data line DL. For example, the sub-pixel SPX may be connected to the write scan line GWL, the initialization scan line GIL, the bias scan line GBL, the emission control line EL, and the data line DL.

The sub-pixel SPX according to one or more embodiments may include a driving transistor DT, switch elements, a capacitor C1, and a light emitting element LE. In one or more embodiments, the switch elements may include first to sixth transistors ST1, ST2, ST3, ST4, ST5, and ST6.

The driving transistor DT includes a gate electrode, a first electrode, and a second electrode. The driving transistor DT controls the driving current Ids flowing between the first electrode and the second electrode according to a data voltage applied to the gate electrode.

The light emitting element LE may be electrically connected to the driving transistor DT, and may be to emit light with a luminance corresponding to the driving current Ids. In one or more embodiments, the light emitting element LE may be electrically connected between a node where the first electrode of the fourth transistor ST4 and the second electrode of the sixth transistor ST6 are connected, and a second power line VSL to which a second driving voltage is applied. In one or more embodiments, the light emitting element LE may be a micro light emitting diode. Although the sub-pixel SPX including one light emitting element LE is illustrated in FIG. 4, the sub-pixel SPX may include a plurality of light emitting elements LE.

The capacitor C1 is formed between the gate electrode of the driving transistor DT and a first power line VDL to which a first driving voltage VDD is applied. The first driving voltage VDD may be a voltage of a level higher than that of the second driving voltage VSS. One electrode of the capacitor C1 may be connected to the gate electrode of the driving transistor DT, and the other electrode thereof may be connected to the first power line VDL.

In one or more embodiments, as shown in FIG. 4, the first to sixth transistors ST1 to ST6, and the driving transistor DT may all be formed as p-type metal oxide semiconductor field effect transistors (MOSFETs) as shown in FIG. 4. The active layer of each of the driving transistor DT and the first to sixth transistors ST1 to ST6 may include polysilicon.

The gate electrode of the first transistor ST1 and the gate electrode of the second transistor ST2 may be connected to the write scan line GWL, the gate electrode of the third transistor ST3 may be connected to the initialization scan line GIL, and the gate electrode of the fourth transistor ST4 may be connected to the bias scan line GBL. In the case where the first to sixth transistors ST1, ST2, ST3, ST4, ST5, and ST6 are formed as p-type MOSFETs, the first to sixth transistors ST1, ST2, ST3, ST4, ST5, and ST6 may be turned on if (e.g., when) a scan signal of a gate low voltage and an emission control signal of a gate low voltage are applied to each of the initialization scan line GIL, the write scan line GWL, the bias scan line GBL, and the emission line EL. One electrode of the third transistor ST3 may be connected to a first initialization voltage line VIL to which the third driving voltage VINT is applied, and one electrode of the fourth transistor ST4 may be connected to a second initialization voltage line VAIL to which the fourth driving voltage VAINT is applied. The third driving voltage VINT and the fourth driving voltage VAINT may be different voltages. Further, the third driving voltage VINT and the fourth driving voltage VAINT may be voltages of a level lower than that of the first driving voltage VDD and a level higher than that of the second driving voltage VSS.

In one or more embodiments, the driving transistor DT, the second transistor ST2, the fourth transistor ST4, the fifth transistor ST5, and the sixth transistor ST6 may be configured as p-type metal oxide semiconductor field effect transistors (MOSFETs), and the first transistor ST1 and the third transistor ST3 may be configured as n-type MOSFETs. In this case, an active layer of each of the driving transistor DT, the second transistor ST2, the fourth transistor ST4, the fifth transistor ST5 and the sixth transistor ST6 configured as the p-type MOSFETs may include polysilicon, whereas an active layer of each of the first transistor ST1 and the third transistor ST3 configured as the n-type MOSFETs may include an oxide semiconductor. In one or more embodiments, because the first transistor ST1 and the third transistor ST3 are formed as n-type MOSFETs, the first transistor ST1 may be turned on when a scan signal of a gate high voltage (e.g., a write scan signal of a gate high voltage) is applied, and the third transistor ST3 may be turned on when a scan signal of a gate high voltage (e.g., an initialization scan signal of a gate high voltage) is applied. Further, because the second transistor ST2, the fourth transistor ST4, the fifth transistor ST5, and the sixth transistor ST6 are configured as the p-type MOSFETs, they may be turned on when an emission control signal of a gate low voltage and a scan signal of a gate low voltage are applied.

In one or more embodiments, the fourth transistor ST4 may be formed as an n-type MOSFET, and the other transistors DT, ST1, ST2, ST3, ST5, and ST6 may be formed as p-type MOSFETs. In this case, the active layer of the fourth transistor ST4 may include an oxide semiconductor, and the active layer of each of the other transistors DT, ST1, ST2, ST3, ST5, and ST6 may include polysilicon. Further, the fourth transistor ST4 may be turned on when a scan signal of a gate high voltage is applied, whereas the other transistors DT, ST1, ST2, ST3, ST5, and ST6 may be turned on when an emission control signal of a gate low voltage and a scan signal of a gate low voltage are applied.

In one or more embodiments, the first to sixth transistors ST1, ST2, ST3, ST4, ST5, and ST6, and the driving transistor DT may all be formed as n-type MOSFETs. In this case, the active layer of each of the driving transistor DT and the first to sixth transistors ST1, ST2, ST3, ST4, ST5, and ST6 may include an oxide semiconductor, and may be turned on when an emission control signal of a gate high voltage and a scan signal of a gate high voltage are applied.

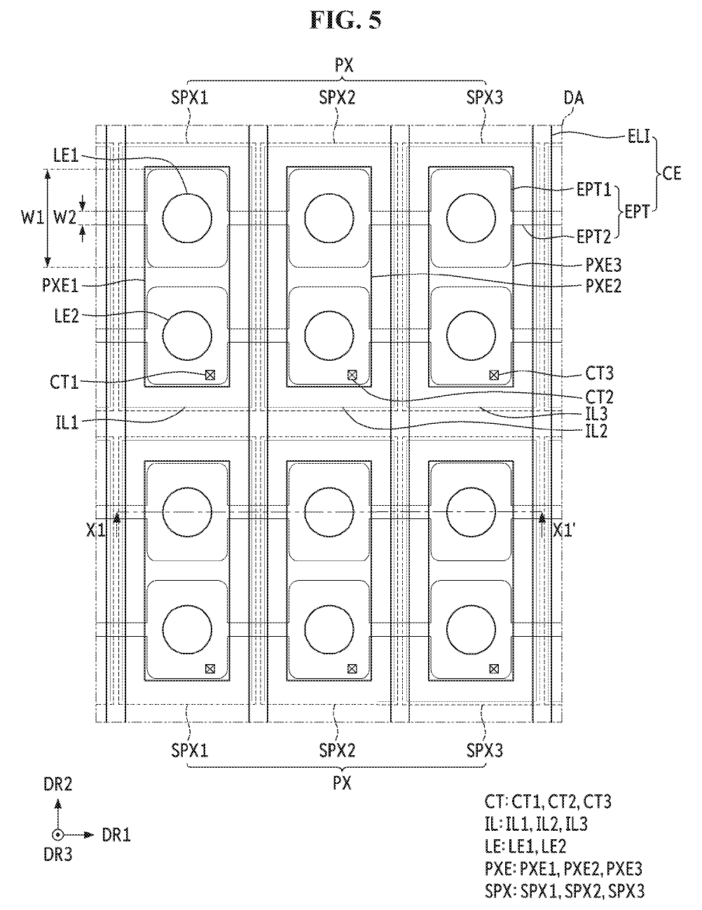

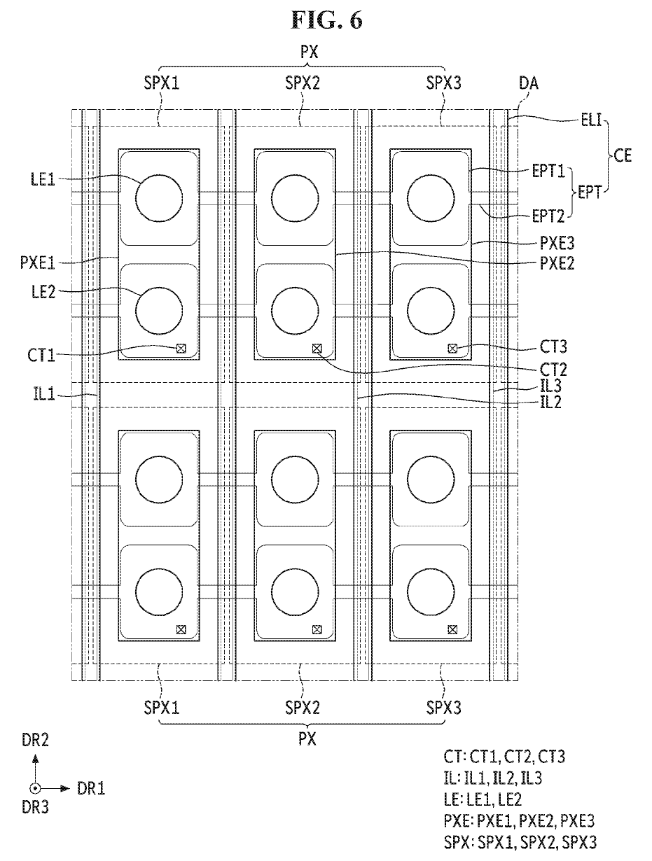

FIG. 5 is a plan view illustrating a display area of a display panel according to one or more embodiments. FIG. 6 is a plan view illustrating a display area of a display panel according to one or more embodiments. For example, FIGS. 5 and 6 show a part of the display area DA including two pixels PX sequentially arranged in the second direction DR2. FIGS. 5 and 6 show different embodiments of an insulating layer IL located around the light emitting elements LE.

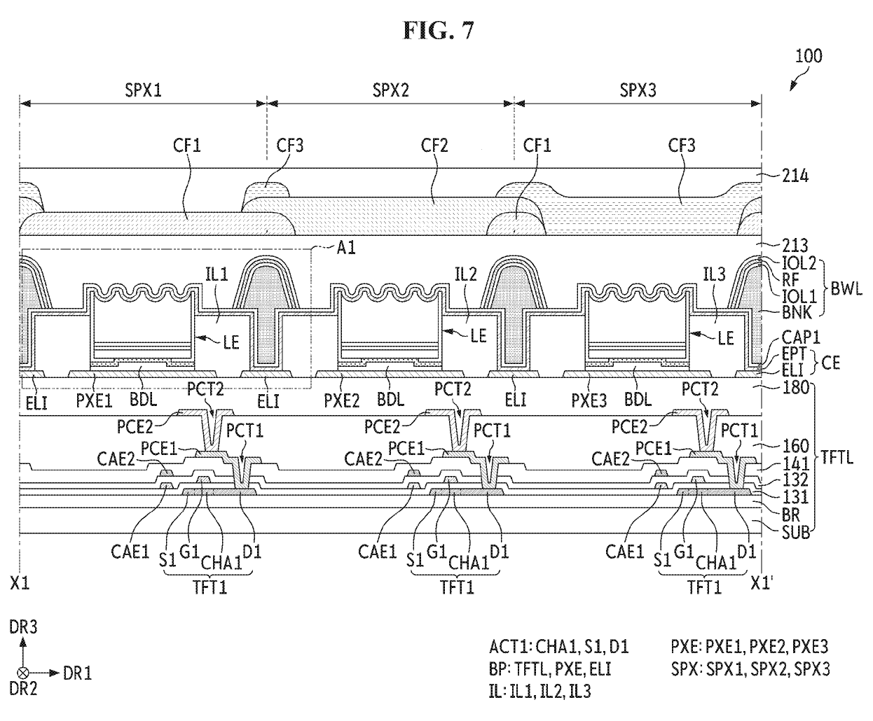

FIGS. 5 and 6 show embodiments of a layout structure of a light emitting element layer including light emitting elements LE of the sub-pixels SPX among elements included in the display panel 100 (see FIGS. 1 to 3). The display panel 100 may further include a circuit layer (for example, a thin film transistor layer TFTL of FIG. 7) including circuit elements (for example, transistors and a capacitor C1 of FIG. 4) of each of the sub-pixels SPX.

Referring to FIGS. 5 and 6, in addition to FIGS. 1 to 4, the display panel 100 according to one or more embodiments may include the pixels PX located in the display area DA. Each pixel PX may include the plurality of sub-pixels SPX.

In one or more embodiments, each pixel PX may include a first sub-pixel SPX1 to emit light of a first color, a second sub-pixel SPX2 to emit light of a second color, and a third sub-pixel SPX3 to emit light of a third color. In one or more embodiments, the light of the first color, the light of the second color, and the light of the third color may be red light (for example, light in a red wavelength band having a main peak wavelength of about 600 nm to 750 nm), green light (for example, light in a green wavelength band having a main peak wavelength of about 480 nm to 560 nm), and blue light (for example, light in a blue wavelength band having a main peak wavelength of about 370 nm to 460 nm), respectively. However, embodiments are not limited thereto, and the types (kinds), numbers, ratios, and/or combinations of the sub-pixels SPX forming each pixel PX may be variously changed according to one or more embodiments.

In one or more embodiments, the first sub-pixel SPX1, the second sub-pixel SPX2, and the third sub-pixel SPX3 of each of the pixels PX may be sequentially arranged in the first direction DR1. However, the arrangement shape and/or direction of the sub-pixels SPX forming each pixel PX may be variously changed according to one or more embodiments. Each sub-pixel SPX may include a pixel electrode PXE and at least one light emitting element LE located on the pixel electrode PXE.

In one or more embodiments, each sub-pixel SPX may include the plurality of light emitting elements LE. For example, the first sub-pixel SPX1 may include a first pixel electrode PXE1, and a first light emitting element LE1 and a second light emitting element LE2 that are located on the first pixel electrode PXE1. In one or more embodiments, the second sub-pixel SPX2 may include a second pixel electrode PXE2, and a first light emitting element LE1 and a second light emitting element LE2 that are located on the second pixel electrode PXE2, and the third sub-pixel SPX3 may include a third pixel electrode PXE3, and a first light emitting element LE1 and a second light emitting element LE2 that are located on the third pixel electrode PXE3. In describing the present embodiments, the first light emitting element LE1 and the second light emitting element LE2 distinguish and refer to different light emitting elements LE included in each sub-pixel SPX, and the first light emitting element LE1 and the second light emitting element LE2 may also be collectively referred to as the light emitting element LE.

Although one or more embodiments in which the first sub-pixel SPX1, the second sub-pixel SPX2, and the third sub-pixel SPX3 include the same number of light emitting elements LE (for example, two light emitting elements LE) is illustrated in FIGS. 5 and 6, embodiments are not limited thereto. For example, at least two sub-pixels SPX among the first sub-pixel SPX1, the second sub-pixel SPX2, and the third sub-pixel SPX3 may include different numbers of light emitting elements LE.

The light emitting elements LE of each sub-pixel SPX may be connected in parallel. For example, the first light emitting element LE1 and the second light emitting element LE2 of each of the sub-pixels SPX may be connected in parallel between the pixel electrode PXE and the common electrode CE of the corresponding sub-pixel SPX.

In one or more embodiments, the light emitting elements LE of each sub-pixel SPX may be arranged in the second direction DR2. For example, the first light emitting element LE1 and the second light emitting element LE2 of each sub-pixel SPX may be arranged in the second direction DR2 on the pixel electrode PXE of the corresponding sub-pixel SPX. However, the embodiments are not limited thereto. For example, the first light emitting element LE1 and the second light emitting element LE2 are not necessarily arranged in a row in the second direction DR2, and the center of the first light emitting element LE1 and the center of the second light emitting element LE2 may be arranged in a diagonal direction deviated from the second direction DR2 by a slight angle.

The pixel electrodes PXE may be spaced apart from each other. For example, the first pixel electrode PXE1, the second pixel electrode PXE2, and the third pixel electrode PXE3 of each pixel PX may be arranged in the first direction DR1 in each pixel area where each pixel PX is located, and may be spaced apart from each other. In one or more embodiments, in the entire display area DA, the pixel electrodes PXE and the sub-pixels SPX including the pixel electrodes PXE may be arranged in the first direction DR1 and the second direction DR2. In one or more embodiments, each of the pixel electrodes PXE may have a substantially rectangular planar shape, but the shape and/or size of each of the pixel electrodes PXE may vary depending on embodiments.

The pixel electrode PXE may be electrically connected to the circuit element included in each sub-pixel SPX through each connection hole CT. For example, the first pixel electrode PXE1 may be electrically connected to at least one circuit element (for example, the fourth transistor ST4 and the sixth transistor ST6 included in the first sub-pixel SPX1) included in the first sub-pixel SPX1 through a first connection hole CT1. Similarly, the second pixel electrode PXE2 may be electrically connected to at least one circuit element (for example, the fourth transistor ST4 and the sixth transistor ST6 included in the second sub-pixel SPX2) included in the second sub-pixel SPX2 through a second connection hole CT2, and the third pixel electrode PXE3 may be electrically connected to at least one circuit element (for example, the fourth transistor ST4 and the sixth transistor ST6 included in the third sub-pixel SPX3) included in the third sub-pixel SPX3 through a third connection hole CT3.

In one or more embodiments, the pixel electrode PXE may be electrically connected to the light emitting element LE included in each sub-pixel SPX. For example, the first pixel electrode PXE1 may be electrically connected to a first semiconductor layer (for example, a p-type semiconductor layer) of each of the first light emitting element LE1 and the second light emitting element LE2 included in the first sub-pixel SPX1. Similarly, the second pixel electrode PXE2 may be electrically connected to a first semiconductor layer of each of the first light emitting element LE1 and the second light emitting element LE2 included in the second sub-pixel SPX2, and the third pixel electrode PXE3 may be electrically connected to a first semiconductor layer of each of the first light emitting element LE1 and the second light emitting element LE2 included in the third sub-pixel SPX3.

In one or more embodiments, the plurality of light emitting elements LE included in each sub-pixel SPX may be light emitting elements LE of the same type or kind. For example, the first light emitting element LE1 and the second light emitting element LE2 may be vertical type or kind micro LEDs, and may be to emit light of the same color. In one or more embodiments, the structure and/or size of the first light emitting element LE1 and the second light emitting element LE2 may be substantially the same.

In one or more embodiments, the sub-pixels SPX of each pixel PX may include the light emitting elements LE emitting (e.g., configured to emit) light of different colors. For example, the first light emitting element LE1 and the second light emitting element LE2 of the first sub-pixel SPX1 may be red light emitting elements to emit red light, the first light emitting element LE1 and the second light emitting element LE2 of the second sub-pixel SPX2 may be green light emitting elements to emit green light, and the first light emitting element LE1 and the second light emitting element LE2 of the third sub-pixel SPX3 may be blue light emitting elements to emit blue light. When each pixel PX includes four sub-pixels SPX, the four sub-pixels SPX may be to emit light of different colors (for example, red light, green light, blue light, and white light), or each of the four sub-pixels SPX may be to emit light of a set or specific color (for example, red light, green light, or blue light), and two of the four sub-pixels SPX may be to emit light of the same color.

In some embodiments, the sub-pixels SPX of each pixel PX may include the light emitting elements LE emitting (e.g., configured to emit) light of the same color. For example, the first light emitting element LE1 and the second light emitting element LE2 of each of the first sub-pixel SPX1, the second sub-pixel SPX2, and the third sub-pixel SPX3 may be light emitting elements to emit blue light or white light. When at least one sub-pixel SPX includes the light emitting elements LE to emit light of a color (or wavelength) different from the emission color (or emission wavelength) of the corresponding sub-pixel (SPX), a color filter and/or a light conversion layer for converting the light emitted from the light emitting elements LE into light corresponding to the emission color (or emission wavelength) of the sub-pixel SPX may be located on the light emitting elements LE of the sub-pixel SPX.

The display panel 100 according to one or more embodiments may further include the common electrode CE commonly connected to the light emitting elements LE of the sub-pixels SPX. For example, the pixels PX including the respective sub-pixels SPX may substantially share one common electrode CE, and the light emitting elements LE of the sub-pixels SPX may be electrically connected to the common electrode CE. The common electrode CE may be electrically connected to the second semiconductor layer (e.g., an n-type or kind semiconductor layer) of each of the light emitting elements LE. The pixel electrodes PXE may also be referred to as an anode electrode or a first electrode, and the common electrode CE may also be referred to as a cathode electrode or a second electrode.

The common electrode CE may be electrically connected to the second power line VSL (see FIG. 4) in the display area DA and/or around the display area DA (e.g., a part of the non-display area NDA adjacent to the display area DA. For example, a part of the common electrode CE may be located in a part of the non-display area NDA adjacent to the display area DA, and may be electrically connected to the second power line VSL or may form the second power line VSL in the non-display area NDA. In one or more embodiments, the second power line VSL may be located in the display area DA, and the common electrode CE and the second power line VSL may be electrically connected to each other in the display area DA through at least one connection hole. In one or more embodiments, the connection structure of the common electrode CE and the second power line VSL may be variously suitably changed according to one or more embodiments. The second driving voltage VSS may be applied to the light emitting elements LE of the sub-pixels SPX through the second power line VSL and the common electrode CE.

The common electrode CE according to one or more embodiments may include electrode lines ELI and electrode patterns EPT intersecting each other, and may have a mesh shape as a whole (e.g., overall). For example, the common electrode CE may include the electrode lines ELI arranged in the first direction DR1 and respectively extending in the second direction DR2, and the electrode patterns EPT arranged in the second direction DR2 and respectively extending in the first direction DR1. The electrode lines ELI and the electrode patterns EPT may be electrically connected to each other to form the mesh-shaped common electrode CE.

The electrode lines ELI and the electrode patterns EPT may include different materials. For example, the electrode lines ELI may include a conductive material (for example, a metal having a suitably low resistivity, or a metal film having a suitably low sheet resistance) having a resistivity (or sheet resistance) lower than that of a conductive material included in the electrode patterns EPT.

The electrode lines ELI may be located between the pixel electrodes PXE. For example, the electrode lines ELI and the pixel electrodes PXE may be located alternately in the first direction DR1.

In one or more embodiments, the electrode lines ELI and the pixel electrodes PXE may be formed to be spaced apart from each other in substantially the same layer. For example, after a single-layer or multi-layer conductive film including a low-resistance conductive material (for example, a low-resistance metal having a suitably low resistivity such as copper (Cu), silver (Ag), and/or aluminum (Al)) is formed, the electrode lines ELI and the pixel electrodes PXE may be formed separately from each other by etching the conductive film. In this case, the electrode lines ELI and the pixel electrodes PXE may include the same material.

The electrode patterns EPT may be located on the light emitting elements LE of the sub-pixels SPX. For example, each of the electrode patterns EPT of the common electrode CE may be located on the plurality of light emitting elements LE arranged in the first direction DR1 among the light emitting elements LE located in the display area DA.

The electrode patterns EPT may include a transparent conductive material. For example, the electrode patterns EPT may include a transparent conductive oxide (TCO) having excellent or suitable conductivity and transparency, such as indium tin oxide (ITO) and/or indium zinc oxide (IZO), and may be substantially transparent. Accordingly, light generated from the light emitting elements LE may be transmitted through the electrode patterns EPT and be emitted toward the front side of the display panel 100 (for example, in the third direction DR3).

In one or more embodiments, the electrode patterns EPT may have different widths for each portion. For example, each of the electrode patterns EPT may include first portions EPT1 that overlap the plurality of light emitting elements LE arranged in the first direction DR1 among the light emitting elements LE located in the display area DA and respectively cover the plurality of light emitting elements LE, and second portions EPT2 that connect the first portions EPT1. In one or more embodiments, the electrode patterns EPT may have a relatively wide width at the first portions EPT1 and a relatively narrow width at the second portions EPT2.

For example, the electrode patterns EPT may have a first width W1 greater than the width and/or diameter of the top surfaces of the light emitting elements LE at the first portions EPT1 overlapping the light emitting elements LE, and may completely (e.g., entirely) cover the top surfaces of the light emitting elements LE. Accordingly, the contact area between the common electrode CE and the light emitting elements LE may be stably or suitably secured, and the common electrode CE and the light emitting elements LE may be stably or suitably connected. Each of the first portions EPT1 of the electrode patterns EPT may also be referred to as "contact portion."

In one or more embodiments, the electrode patterns EPT may have a second width W2 less than the first width W1 at the second portions EPT2 located on respective sides of each of the first portions EPT1 and/or between the first portions EPT1. For example, the electrode patterns EPT may be formed as patterns of a bottleneck shape (or bottleneck structure) whose width becomes narrower at a portion that does not overlap the light emitting elements LE and/or the pixel electrodes PXE.

The second portions EPT2 of the electrode patterns EPT may connect the first portions EPT1 of the electrode patterns EPT with each other in the first direction DR1. In one or more embodiments, the second portions EPT2 of the electrode patterns EPT may intersect the electrode lines ELI and may be electrically connected to the electrode lines ELI. For example, the second portions EPT2 of the electrode patterns EPT may be in direct contact with a part of the electrode lines ELI that is not covered by the insulating layer IL. Each of the second portions EPT2 of the electrode patterns EPT may also be referred to as "connection portion."

In one or more embodiments, the second width W2 of the second portions EPT2 of the electrode patterns EPT may be sufficient to allow each of the electrode patterns EPT to be stably or suitably connected without being disconnected in the first direction DR1, and may be suitable for easy disconnection of the electrode patterns EPT by a laser and/or the like if (e.g., when) necessary. For example, the second width W2 of the second portions EPT2 of the electrode patterns EPT may be less than the width and/or diameter of the top surfaces of the light emitting elements LE.

The insulating layer IL may be located between the pixel electrodes PXE and the common electrode CE. For example, the insulating layer IL may be located between the pixel electrodes PXE and the electrode patterns EPT. For example, the insulating layer IL may be located above and around the pixel electrodes PXE to surround the side surfaces of the light emitting elements LE, and the electrode patterns EPT may be located on the light emitting elements LE and the insulating layer IL. Accordingly, direct connection of the pixel electrodes PXE to the common electrode CE may be prevented or reduced, and the electrical stability (for example, insulation property) may be suitably secured between the pixel electrodes PXE and the common electrode CE.

The insulating layer IL may not cover at least a part of the electrode lines ELI. For example, the insulating layer IL may expose a part of the electrode lines ELI at a portion where the electrode lines ELI and the electrode patterns EPT intersect, and may cover another part (for example, edge portion) of the electrode lines ELI.

The electrode patterns EPT (for example, the second portions EPT2 of the electrode patterns EPT) may be in contact with a part of the electrode lines ELI that is exposed without being covered by the insulating layer IL. Accordingly, the electrode lines ELI and the electrode patterns EPT may be electrically connected, thereby forming the mesh-shaped common electrode CE.

In one or more embodiments, the insulating layer IL may include a plurality of insulating patterns separated at least in the first direction DR1. For example, the insulating layer IL may include island-shaped insulating patterns spaced apart from each other in the first direction DR1 and the second direction DR2, or may include line-shaped (e.g., elongated) insulating patterns spaced apart from each other in the first direction DR1 and respectively extending in the second direction DR2.

In one or more embodiments, the insulating layer IL may include island-shaped insulating patterns that are individually located in the respective sub-pixels SPX including the respective pixel electrodes PXE, and are separated from each other, as illustrated in FIG. 5. For example, the insulating layer IL may include a first insulating pattern IL1 located in each first sub-pixel SPX1 and around (e.g., surrounding) the light emitting elements LE located in each first sub-pixel SPX1, a second insulating pattern IL2 located in each second sub-pixel SPX2 and around (e.g., surrounding) the light emitting elements LE located in each second sub-pixel SPX2, and a third insulating pattern IL3 located in each third sub-pixel SPX3 and around (e.g., surrounding) the light emitting elements LE located in each third sub-pixel SPX3. In this case, the insulating layer IL may include the first insulating patterns IL1, the second insulating patterns IL2, and the third insulating patterns IL3 that are arranged in the display area DA to correspond to the arrangement shape of the first sub-pixels SPX1, the second sub-pixels SPX2, and the third sub-pixels SPX3, and are spaced apart from each other. A part of each of the electrode lines ELI may be exposed between the island-shaped insulating patterns. Accordingly, the electrode lines ELI and the electrode patterns EPT of the common electrode CE may be electrically connected to each other. For example, the electrode patterns EPT of the common electrode CE may be in direct contact with a part of each of the electrode lines ELI of the common electrode CE.

In some embodiments, as illustrated in FIG. 6, the insulating layer IL may include line-shaped (e.g., elongated) insulating patterns that are patterned in a shape and/or size corresponding to a group of sub-pixels arranged in the second direction DR2 in the display area DA (for example, a row of first sub-pixels SPX1 arranged with each other in the second direction DR2, second sub-pixels SPX2 arranged with each other in the second direction DR2, and/or third sub-pixels SPX3 arranged with each other in the second direction DR2) , and are separated from each other in the first direction DR1 and respectively extend in the second direction DR2. For example, the insulating layer IL may include the first insulating pattern IL1 located in the first sub-pixels SPX1 arranged in the second direction DR2 and around (e.g., surrounding) the light emitting elements LE of the first sub-pixels SPX1, the second insulating pattern IL2 located in the second sub-pixels SPX2 arranged in the second direction DR2 and around (e.g., surrounding) the light emitting elements LE of the second sub-pixels SPX2, and the third insulating pattern IL3 located in the third sub-pixels SPX3 arranged in the second direction DR2 and around (e.g., surrounding) the light emitting elements LE of the third sub-pixels SPX3. The first insulating pattern IL1, the second insulating pattern IL2, and the third insulating pattern IL3 may be repeatedly arranged in the first direction DR1. A part of each of the electrode lines ELI may be exposed between the line-shaped insulating patterns. Accordingly, the electrode lines ELI and the electrode patterns EPT of the common electrode CE may be electrically connected to each other.

In one or more embodiments, the insulating layer IL may be formed in the entire display area DA. In this case, the connection holes penetrating the insulating layer IL may be formed at a portion where the electrode lines ELI and the electrode patterns EPT of the common electrode CE intersect, and the electrode lines ELI and the electrode patterns EPT of the common electrode CE may be electrically connected to each other through the connection holes.

FIG. 7 is a cross-sectional view illustrating a display area of a display panel according to one or more embodiments. For example, FIG. 7 illustrates one or more embodiments of a cross-section of the pixel PX corresponding to line X1-X1' of FIG. 5.

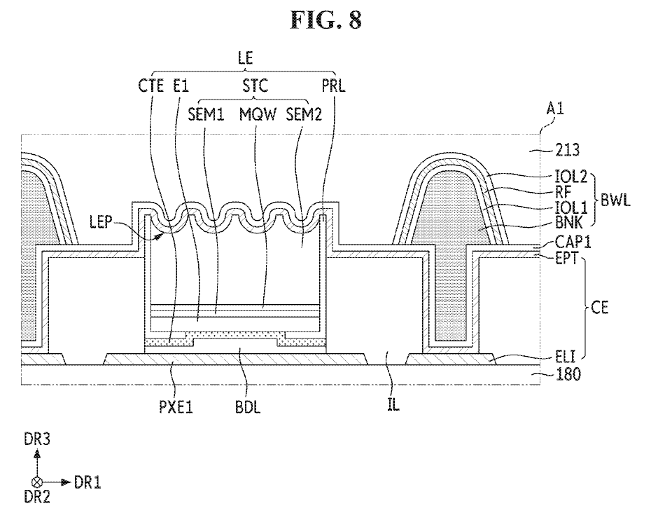

FIG. 8 is a cross-sectional view showing area A1 of FIG. 7 in more detail. For example, FIG. 8 illustrates the light emitting element LE according to one or more embodiments, for example, the light emitting element LE located in area A1 of FIG. 7 in more detail. The light emitting elements LE of the sub-pixels SPX may have substantially the same cross-sectional structure.

Referring to FIGS. 7 and 8, in addition to FIGS. 1 to 6, the display panel 100 according to one or more embodiments may include the thin film transistor layer TFTL including a substrate SUB and circuit elements of the sub-pixels SPX, the pixel electrodes PXE and the electrode lines ELI spaced apart from each other on the thin film transistor layer TFTL, the light emitting elements LE located on the pixel electrodes PXE, and the electrode patterns EPT located on the light emitting elements LE. In one or more embodiments, the display panel 100 may further include the insulating layer IL and a partition wall BWL located around the light emitting elements LE, and the color filters located on the light emitting elements LE.

The thin film transistor layer TFTL, the pixel electrodes PXE, and the electrode lines ELI may form a backplane substrate BP of the display panel 100, and the light emitting elements LE may be located on the backplane substrate BP. For example, the light emitting elements LE may be bonded onto the pixel electrodes PXE of the backplane substrate BP and electrically connected to the respective pixel electrodes PXE. In one or more embodiments, the light emitting elements LE may be covered by the electrode patterns EPT of the common electrode CE, and may be electrically connected to the electrode patterns EPT. Accordingly, the light emitting elements LE may be electrically connected between the respective pixel electrodes PXE and the common electrode CE.

In FIGS. 7 and 8, the thin film transistor TFT1 included in each sub-pixel SPX is illustrated as an example of the circuit elements located in the thin film transistor layer TFTL. The thin film transistor TFT1 may be one of the transistors included in each sub-pixel SPX. For example, the thin film transistor TFT1 may be one selected from among the fourth transistor ST4 and the sixth transistor ST6 illustrated in FIG. 4, and may be electrically connected to the light emitting element LE of each sub-pixel SPX.

The substrate SUB may include an insulating material such as glass and/or polymer resin. When the substrate SUB includes polymer resin, it may be a flexible substrate that can be stretched. The polymer resin may include acrylic resin, epoxy resin, phenolic resin, polyamide resin, and/or polyimide resin.

The barrier layer BR may be located on the substrate SUB. The barrier layer BR may protect the thin film transistors TFT1 and the light emitting elements LE from moisture permeating through the substrate SUB that is susceptible to moisture permeation. In one or more embodiments, the barrier layer BR may include a plurality of inorganic films that are alternately stacked.

The thin film transistor TFT1 of each of the sub-pixels SPX may be located on the barrier layer BR. The thin film transistor TFT1 may include an active layer ACT1 and a gate electrode G1.

The active layer ACT1 of the thin film transistor TFT1 may be located on the barrier layer BR. The active layer ACT1 may include polycrystalline silicon, monocrystalline silicon, low-temperature polycrystalline silicon, and/or amorphous silicon. In one or more embodiments, the active layer ACT1 may include an oxide semiconductor (for example, indium gallium zinc oxide (IGZO), indium gallium zinc tin oxide (IGZTO), and/or indium gallium tin oxide (IGTO)).

The active layer ACT1 may include a channel region CHA1, a source region S1, and a drain region D1. The channel region CHA1 may overlap the gate electrode G1 in the third direction DR3. The source region S1 may be located on one side of the channel region CHA1, and the drain region D1 may be located on the other side of the channel region CHA1. At least a part of the source region S1 and the drain region D1 may not overlap the gate electrode G1 in the third direction DR3. The conductivity (for example, carrier concentration) of the source region S1 and the drain region D1 may be higher than the conductivity of the channel region CHA1.

The first gate insulating layer 131 may be located on the active layer ACT1.

A first gate metal layer may be located on the first gate insulating layer 131. The first gate metal layer may include the gate electrode G1 and the first capacitor electrode CAE1 of the thin film transistor TFT1.

The gate electrode G1 and the active layer ACT1 included in each thin film transistor TFT1 may overlap each other in the third direction DR3. For example, the gate electrode G1 may overlap the channel region CHA1 of the active layer ACT1 in the third direction DR3.

The first capacitor electrode CAE1 may form one electrode of a capacitor, for example, the capacitor C1 of FIG. 4, included in each sub-pixel SPX. In one or more embodiments, the first capacitor electrode CAE1 may be formed integrally with the gate electrode of the driving transistor DT of FIG. 4, and may be formed separately from the gate electrodes of the first to sixth transistors ST1, ST2, ST3, ST4, ST5, and ST6 of FIG. 4.

A second gate insulating layer 132 may be located on the gate electrode G1 and the first capacitor electrode CAE1 of the thin film transistor TFT1.

A second gate metal layer may be located on the second gate insulating layer 132. The second gate metal layer may include a second capacitor electrode CAE2. The second capacitor electrode CAE2 may overlap the first capacitor electrode CAE1 in the third direction DR3. A capacitor (e.g., the capacitor C1 of FIG. 4) may be formed by the first capacitor electrode CAE1, the second capacitor electrode CAE2, and the second gate insulating layer 132.

An interlayer insulating layer 141 may be located on the second capacitor electrode CAE2.

A first data metal layer may be located on the interlayer insulating layer 141. The first data metal layer may include a first source connection electrode PCE1. The first source connection electrode PCE1 may be electrically connected to the drain region D1 of the thin film transistor TFT1 through a first source contact hole PCT1 penetrating the first gate insulating layer 131, the second gate insulating layer 132, and the interlayer insulating layer 141.

A first planarization layer 160 may be located on the first source connection electrode PCE1. The first planarization layer 160 may alleviate (e.g., reduce or substantially flatten) a stepped portion caused by the thin film transistor TFT1.

A second data metal layer may be located on the first planarization layer 160. The second data metal layer may include a second source connection electrode PCE2. The second source connection electrode PCE2 may be electrically connected to the first source connection electrode PCE1 through a second source contact hole PCT2 penetrating the first planarization layer 160.

A second planarization layer 180 may be located on the second source connection electrode PCE2. The second planarization layer 180 may alleviate (e.g., reduce or substantially flatten) stepped portions caused by circuit elements and wires of the thin film transistor layer TFTL.

The barrier layer BR, the first gate insulating layer 131, the second gate insulating layer 132, and the interlayer insulating layer 141 may be formed as at least one inorganic insulating layer including an inorganic insulating material (for example, silicon nitride (SiNₓ, e.g., Si₃N₄), silicon oxynitride (SiOₓN_{y}), silicon oxide (SiOₓ, e.g., SiO₂), titanium oxide (TiOₓ, TiO₂), and/or aluminum oxide (AlOₓ, e.g., Al₂O₃)). Each of the barrier layer BR, the first gate insulating layer 131, the second gate insulating layer 132, and the interlayer insulating layer 141 may be formed in a single-layer or multi-layer structure.

The first gate metal layer, the second gate metal layer, the first data metal layer, and the second data metal layer may include a conductive material (for example, any one selected from among molybdenum (Mo), aluminum (Al), chromium (Cr), gold (Au), titanium (Ti), nickel (Ni), neodymium (Nd), and copper (Cu), and/or an alloy thereof). Each of the first gate metal layer, the second gate metal layer, the first data metal layer, and the second data metal layer may be formed in a single-layer or multi-layer structure.

The first planarization layer 160 and the second planarization layer 180 may include at least one organic insulating layer containing an organic insulating material (e.g., acrylic resin, epoxy resin, phenolic resin, polyamide resin, polyimide resin, and/or the like). Each of the first planarization layer 160 and the second planarization layer 180 may be formed in a single-layer or multi-layer structure.

A light emitting element layer may be located on the second planarization layer 180. The light emitting element layer may include the pixel electrodes PXE, the common electrode CE, and the light emitting elements LE. The light emitting element layer may further include the insulating layer IL (for example, an organic insulating layer) located around the light emitting elements LE, a first capping layer CAP1, the partition wall BWL, and a third planarization layer 213 (for example, an organic insulating layer).

The pixel electrode layer may be located on the second planarization layer 180. The pixel electrode layer may include the pixel electrodes PXE (for example, the first pixel electrode PXE1, the second pixel electrode PXE2, and the third pixel electrode PXE3) of the sub-pixels SPX, and the electrode lines ELI of the common electrode CE.

Each of the pixel electrodes PXE may be electrically connected to the second source connection electrode PCE2 of each sub-pixel SPX through a connection hole CT (for example, the first connection hole CT1, a second connection hole CT2, and/or a third connection hole CT3 of FIG. 5) penetrating the second planarization layer 180. Each of the pixel electrodes PXE may be electrically connected to the thin film transistor TFT1 included in the corresponding sub-pixel SPX via the first source connection electrode PCE1 and the second source connection electrode PCE2. Accordingly, a voltage controlled or selected by the thin film transistor TFT1 or a driving transistor (for example, the driving transistor DT of FIG. 4) electrically connected to the thin film transistor TFT1 may be applied to each pixel electrode PXE.

The electrode lines ELI of the common electrode CE may be electrically connected to the second power line VSL in the display area DA and/or the non-display area NDA. Accordingly, the second driving voltage VSS may be applied to the electrode lines ELI.

The pixel electrode layer may include a conductive material (e.g., any one selected from among molybdenum (Mo), aluminum (Al), chromium (Cr), gold (Au), titanium (Ti), nickel (Ni), neodymium (Nd) and copper (Cu), and/or an alloy thereof), and may be formed as a single layer or multiple layers. For example, the pixel electrodes PXE and the electrode lines ELI may each be formed in a single-layer or multi-layer conductive pattern including at least one conductive material. The pixel electrodes PXE and the electrode lines ELI may be formed concurrently (e.g., simultaneously), and may include the same conductive material.

In one or more embodiments, the pixel electrode layer may include a conductive material having a suitably low resistance (for example, a metal or metal film having a suitably low resistivity or a suitably low sheet resistance). Accordingly, the resistance of the patterns, for example, the pixel electrodes PXE and the electrode lines ELI, of the pixel electrode layer may be reduced.

In one or more embodiments, the pixel electrode layer may include a reflective layer including a metal with suitably high reflectivity. For example, the pixel electrodes PXE and the electrode lines ELI may each include a first layer made of any one selected from among molybdenum (Mo), aluminum (Al), chromium (Cr), gold (Au), titanium (Ti), nickel (Ni), neodymium (Nd), and copper (Cu), and/or an alloy thereof, and a second layer (reflective layer) made of a metal material having a suitably high reflectivity, such as aluminum (Al), and located on the first layer. Accordingly, the luminance and light efficiency of the sub-pixels SPX may be improved by reflecting the downward light of the light emitting elements LE.

The light emitting elements LE may be located on the respective pixel electrodes PXE. For example, the light emitting element LE of the first sub-pixel SPX1 may be located on the first pixel electrode PXE1, the light emitting element LE of the second sub-pixel SPX2 may be located on the second pixel electrode PXE2, and the light emitting element LE of the third sub-pixel SPX3 may be located on the third pixel electrode PXE3.

In one or more embodiments, a bonding layer BDL may be located between the pixel electrodes PXE and the light emitting elements LE. The bonding layer BDL may include a material for stably or suitably locating and/or bonding each light emitting element LE on each pixel electrode PXE. For example, the light emitting elements LE may be stably or suitably bonded onto the respective pixel electrodes PXE via the bonding layer BDL. In one or more embodiments, when the light emitting elements LE are bonded onto the respective pixel electrodes PXE by a eutectic bonding method and/or a solder bonding method, the bonding layer BDL may include a metal such as a eutectic alloy and/or a solder alloy (for example, a tin (Sn)-silver (Ag)-copper (Cu) alloy). In one or more embodiments, the material of the bonding layer BDL may be variously changed depending on the bonding method of the light emitting elements LE. In some embodiments, the bonding layer BDL may not be provided.

The light emitting elements LE may be located on the respective pixel electrodes PXE and/or the bonding layer BDL. The light emitting elements LE according to one or more embodiments may be a vertical type or kind micro LED. The vertical type or kind micro LED may refer to an LED having a structure in which a first semiconductor layer SEM1, an active layer MQW, and a second semiconductor layer SEM2 are sequentially arranged in the third direction DR3 that is a vertical direction.

In one or more embodiments, each light emitting element LE may include a substantially vertical side surface as illustrated in FIG. 8. For example, the light emitting element LE may be patterned by vertical etching, and may have a rectangular or square cross-sectional shape in which the width of the top surface and the width of the bottom surface are substantially the same. The shape of the light emitting element LE may be variously changed according to one or more embodiments. For example, the light emitting element LE may have a reverse tapered cross-sectional shape. For example, the light emitting element LE may have an inverted trapezoidal cross-sectional shape in which the width of the top surface is wider than the width of the bottom surface.

In one or more embodiments, each light emitting element LE may be an inorganic micro LED including an inorganic material. For example, the light emitting element LE may include an inorganic material such as gallium nitride (GaN). Further, the light emitting element LE may have a length of several μm to several hundred μm in each of the first direction DR1, the second direction DR2, and the third direction DR3. For example, the light emitting element LE may have a length of 100 µm or less

in each of the first direction DR1, the second direction DR2, and the third direction DR3. In one or more embodiments, the light emitting element LE may have a length of approximately 6 μm to 10 μm or less in each of the first direction DR1, the second direction DR2, and the third direction DR3.

The light emitting elements LE may be formed by growing on a semiconductor substrate such as a silicon substrate and/or sapphire substrate. The light emitting elements LE may be transferred directly from the semiconductor substrate onto the pixel electrodes PXE of the backplane substrate BP. In some embodiments, each of the light emitting elements LE may be transferred onto the pixel electrodes PXE of the backplane substrate BP through an electrostatic method using an electrostatic head and/or a stamping method using an elastic polymer material such as PDMS and/or silicon as a transfer substrate.

Each light emitting element LE may include a semiconductor stack STC and a protective film PRL. In one or more embodiments, the light emitting element LE may further include a conductive layer E1 and a contact electrode CTE.

The semiconductor stack STC may include the first semiconductor layer SEM1, the active layer MQW, and the second semiconductor layer SEM2 that are sequentially arranged on the first semiconductor layer SEM1. For example, the semiconductor stack STC may have a structure in which the first semiconductor layer SEM1, the active layer MQW, and the second semiconductor layer SEM2 are sequentially stacked in the third direction DR3. In one or more embodiments, the semiconductor stack STC may selectively further include an additional semiconductor layer. For example, the semiconductor stack STC may further include at least one selected from among an electron blocking layer located between the first semiconductor layer SEM1 and the active layer MQW, a superlattice layer located between the active layer MQW and the second semiconductor layer SEM2, and an undoped or lightly doped semiconductor layer located on the second semiconductor layer SEM2.

The conductive layer E1 may be located on the bottom surface of the first semiconductor layer SEM1.FIG. 8 illustrates that the conductive layer E1 covers the entire bottom surface of the first semiconductor layer SEM1, but the embodiments are not limited thereto. For example, the conductive layer E1 may be located only on a portion of the bottom surface of the first semiconductor layer SEM1. The conductive layer E1 may include a conductive material (e.g., any one selected from among molybdenum (Mo), aluminum (Al), chromium (Cr), gold (Au), titanium (Ti), nickel (Ni), neodymium (Nd), and copper (Cu), and/or a transparent conductive material such as metal oxide).

The first semiconductor layer SEM1 may be located on the conductive layer E1. The first semiconductor layer SEM1 may be formed as a semiconductor material layer doped with a first conductivity type dopant such as magnesium (Mg), zinc (Zn), calcium (Ca), strontium (Sr), and/or barium (Ba), for example, gallium nitride (GaN). The first semiconductor layer SEM1 may be electrically connected to each pixel electrode PXE. For example, the first semiconductor layer SEM1 may be electrically connected to each pixel electrode PXE via the conductive layer E1, the contact electrode CTE, and the bonding layer BDL.

The active layer MQW may be located on the first semiconductor layer SEM1. The active layer MQW may be to emit light by recombination of electron-hole pairs according to an electrical signal applied through the first semiconductor layer SEM1 and the second semiconductor layer SEM2.

The active layer MQW may include a material having a single or multiple quantum well structure. When the active layer MQW contains a material having a multiple quantum well structure, the active layer MQW may have the structure in which a plurality of well layers and barrier layers are alternately stacked. In one or more embodiments, the well layer may be formed of indium gallium nitride (InGaN), and the barrier layer may be formed of gallium nitride (GaN) and/or aluminum gallium nitride (AlGaN), but embodiments are not limited thereto.

In one or more embodiments, the active layer MQW may have a structure in which semiconductor materials having large band gap energy and semiconductor materials having small band gap energy are alternately stacked, and may include other group III to V semiconductor materials according to the wavelength band of the emitted light.

When the active layer MQW includes indium gallium nitride (InGaN), the color of emitted light may vary depending on the content (e.g., amount) of indium (In). For example, as the content (e.g., amount) of indium (In) increases, the wavelength band of the light emitted by the active layer MQW may shift to the red wavelength band, and as the content (e.g., amount) of indium (In) decreases, the wavelength band of the light emitted by the active layer MQW may shift to the blue wavelength band. For example, the content (e.g., amount) of indium (In) of the active layer MQW included in the light emitting element LE emitting light in the green wavelength band may be higher than the content (e.g., amount) of indium (In) of the active layer MQW included in the light emitting element LE emitting light in the blue wavelength band, and may be lower than the content (e.g., amount) of indium (In) of the active layer MQW included in the light emitting element LE emitting light in the red wavelength band. In one or more embodiments, the active layer MQW of the light emitting element LE that is to emit light in the blue wavelength band may contain about 10 wt% to 20 wt% of indium.

The second semiconductor layer SEM2 may be located on the active layer MQW. The second semiconductor layer SEM2 may be a semiconductor material layer, for example, gallium nitride (GaN), doped with a second conductivity type or kind dopant such as silicon (Si), germanium (Ge), and/ or tin (Sn). The second semiconductor layer SEM2 may be electrically connected to the common electrode CE. For example, the second semiconductor layer SEM2 may be in contact with and electrically connected to the electrode pattern EPT located on each light emitting element LE.

In one or more embodiments, light extraction patterns LEP may be formed on the top surface of the semiconductor stack STC. For example, the light extraction patterns LEP may be formed on the top surface of the second semiconductor layer SEM2.

The light extraction patterns LEP may be patterns for increasing the efficiency of light emitted from the top surface of the light emitting element LE. For example, the light extraction patterns LEP may be concave patterns formed in a hemispherical or semi-ellipsoidal shape. In this case, the light extraction patterns LEP may have a semicircular or semi-elliptical cross-sectional shape.

The protective film PRL may be a film for protecting the bottom surface and the side surface of the light emitting element LE. For example, the protective film PRL may be located on the bottom surface and side surface of the conductive layer E1, and the side surface of the semiconductor stack STC. For example, the protective film PRL may be located on the bottom surface and side surface of the conductive layer E1, the side surface of the first semiconductor layer SEM1, the side surface of the active layer MQW, and the side surface of the second semiconductor layer SEM2. The protective film PRL may be formed as an inorganic film, for example, a single layer or multi-layer inorganic film including at least one selected from among silicon nitride (SiNₓ, e.g., Si₃N₄), silicon oxynitride (SiOₓN_{y}), silicon oxide (SiOₓ, e.g., SiO₂), titanium oxide (TiOₓ, TiO₂), and/or aluminum oxide (AlOₓ, e.g., Al₂O₃).

An opening that exposes a part of the conductive layer E1 may be formed in the protective film PRL. For example, the protective film PRL may not cover a part of the bottom surface of the conductive layer E1. The conductive layer E1 and the contact electrode CTE may be in contact with each other at the portion where the conductive layer E1 is exposed.

The contact electrode CTE may be located on the bottom surface of the light emitting element LE. For example, the contact electrode CTE may be located on a part of the bottom surface of the conductive layer E1 that is covered by the protective film PRL, and another portion of the bottom surface of the conductive layer E1 that is exposed without being covered by the protective film PRL. Accordingly, the contact electrode CTE may be electrically connected to the conductive layer E1. In one or more embodiments, the contact electrode CTE may be electrically connected to the first semiconductor layer SEM1 through the conductive layer E1.

The contact electrode CTE may be in contact with the bonding layer BDL (or the pixel electrode PXE). For example, one surface (for example, the top surface) of the contact electrode CTE may be in contact with the protective film PRL and the conductive layer E1, and the other surface (for example, the bottom surface) of the contact electrode CTE may be bonded onto each pixel electrode PXE via the bonding layer BDL. When the bonding layer BDL is omitted, the contact electrode CTE may be bonded directly onto the pixel electrode PXE.

The contact electrode CTE may include a conductive material (e.g., any one selected from among molybdenum (Mo), aluminum (Al), chromium (Cr), gold (Au), titanium (Ti), nickel (Ni), neodymium (Nd), and copper (Cu), and/or a transparent conductive material such as metal oxide). For example, the contact electrode CTE may be formed as a two-layer structure of chromium (Cr) and gold (Au), a three-layer structure of titanium (Ti), aluminum (Al), and titanium (Ti), or a three-layer structure of indium-tin oxide (ITO), silver (Ag), and indium-tin oxide (ITO) in order to increase or improve reflectivity.

The insulating layer IL may be located on the thin film transistor layer TFTL to surround the light emitting elements LE. For example, the insulating layer IL may be located on the second planarization layer 180, and may cover the side surfaces of the light emitting elements LE. The insulating layer IL may further cover the side surfaces of the patterns, for example, the pixel electrodes PXE and the electrode lines ELI, of the pixel electrode layer.

In one or more embodiments, the insulating layer IL may be formed to have a height lower than the height of the light emitting elements LE to cover a part of the side surfaces of the light emitting elements LE, and the top surfaces of the light emitting elements LE may protrude to a height higher than the insulating layer IL (e.g., may protrude above the insulating layer IL). However, the embodiments are not limited thereto. For example, the insulating layer IL may be formed to have a height higher than the height of the light emitting elements LE, thereby completely covering the side surfaces of the light emitting elements LE.

The insulating layer IL may include at least one insulating material. For example, the insulating layer IL may be formed as an organic film including an organic insulating material such as acrylic resin, epoxy resin, phenolic resin, polyamide resin, polyimide resin, and/or the like. The insulating layer IL may alleviate, reduce, or substantially flatten stepped portions caused by the light emitting elements LE.

The insulating layer IL may expose at least a part of the electrode lines ELI of the common electrode CE. In one or more embodiments, the insulating layer IL may cover a part of the electrode lines ELI (for example, the edge portions of the electrode lines ELI), and may expose another part of the electrode lines ELI. For example, as illustrated in FIGS. 5 and 6, the insulating layer IL may surround the light emitting elements LE located in each sub-pixel SPX, and may be removed between the sub-pixels SPX adjacent in the first direction DR1 and/or the second direction DR2 to expose a part of each of the electrode lines ELI of the common electrode CE. At the portions where the electrode lines ELI of the common electrode CE are exposed, the electrode lines ELI and the electrode patterns EPT of the common electrode CE may be in contact with and electrically connected to each other.

In one or more embodiments, the insulating layer IL may include a plurality of insulating patterns that are formed separately from each other to correspond to the area where each sub-pixel SPX is located, as illustrated in FIG. 5. For example, the insulating layer IL may include the first insulating patterns IL1 located in the area(s) where the respective first sub-pixels SPX1 are located and around (e.g., surrounding) the first light emitting element LE1 and the second light emitting element LE2 of each of

the first sub-pixels SPX1, the second insulating patterns IL2 located in the area where the respective second sub-pixels SPX2 are located and around (e.g., surrounding) the first light emitting element LE1 and the second light emitting element LE2 of each of the second sub-pixels SPX2, and the third insulating patterns IL3 located in the area where the respective third sub-pixels SPX3 are located and around (e.g., surrounding) the first light emitting element LE1 and the second light emitting element LE2 of each of the third sub-pixels SPX3. The patterns of the insulating layer IL, including the first insulating patterns IL1, the second insulating patterns IL2, and the third insulating patterns IL3, may be spaced apart from each other in the first direction DR1 and the second direction DR2.

In some embodiments, as illustrated in FIG. 6, the insulating layer IL may include the first insulating pattern IL1 located in the area where the first sub-pixels SPX1 arranged in the second direction DR2 are located to surround the first light emitting element LE1 and the second light emitting element LE2 of each of the first sub-pixels SPX1 and extend in the second direction DR2, the second insulating pattern IL2 located in the area where the second sub-pixels SPX2 arranged in the second direction DR2 are located to surround the first light emitting element LE1 and the second light emitting element LE2 of each of the second sub-pixels SPX2 and extend in the second direction DR2, and the third insulating pattern IL3 located in the area where the third sub-pixels SPX3 arranged in the second direction DR2 are located to surround the first light emitting element LE1 and the second light emitting element LE2 of each of the third sub-pixels SPX3 and extend in the second direction DR2. The first insulating pattern IL1, the second insulating pattern IL2, and the third insulating pattern IL3 may be spaced apart from each other in the first direction DR1. In one or more embodiments, the patterns of the insulating layer IL, including the first insulating pattern IL1, the second insulating pattern IL2, and the third insulating pattern IL3 may be repeatedly located (e.g., arranged) with each other in the display area DA in the first direction DR1.

In some embodiments, the insulating layer IL may be located in the entire display area DA, and may be located continuously in the first direction DR1 and the second direction DR2. In this case, the insulating layer IL may have connection holes that expose a part of each of the electrode lines ELI of the common electrode CE (for example, a portion intersecting the electrode patterns EPT of the common electrode CE).

The electrode patterns EPT of the common electrode CE may be located on the light emitting elements LE and the insulating layer IL. For example, the electrode patterns EPT may be located on the top surface of the insulating layer IL and the top surface of each of the light emitting elements LE located in the sub-pixels SPX.

The electrode patterns EPT may be a common layer formed commonly in the first sub-pixel SPX1, the second sub-pixel SPX2, and the third sub-pixel SPX3 of each pixel PX. For example, the respective electrode patterns EPT may be located on the light emitting elements LE of the sub-pixels SPX arranged in the first direction DR1 in the display area DA.

The electrode patterns EPT may be in contact with the top surface of each of the light emitting elements LE, and may be electrically connected to the second semiconductor layers SEM2 of the light emitting elements LE. In one or more embodiments, the electrode patterns EPT may be in contact with a part of the top surfaces of the electrode lines ELI that is not covered by the insulating layer IL, and may be electrically connected to the electrode lines ELI. The electrode patterns EPT may form horizontal patterns of the common electrode CE, and the electrode lines ELI may form vertical patterns of the common electrode CE.

The electrode patterns EPT may be formed substantially transparently to transmit light generated from the light emitting elements LE. For example, the electrode patterns EPT may include indium-tin oxide (ITO), indium-zinc oxide (IZO), or other suitable transparent conductive materials, for example, as exemplified above.

The first capping layer CAP1 may be located on the electrode patterns EPT. The first capping layer CAP1 may serve to encapsulate an underlying component.

The first capping layer CAP1 may include a material, for example, an inorganic material, suitable for protecting the light emitting elements LE. For example, the first capping layer CAP1 may be formed as an inorganic film including an inorganic insulating material such as silicon nitride (SiNₓ, e.g., Si₃N₄), silicon oxynitride (SiOₓN_{y}), silicon oxide (SiOₓ, e.g., SiO₂), titanium oxide (TiOₓ, e.g., TiO₂), and/or aluminum oxide (AlOₓ, e.g., Al₂O₃).

The partition wall BWL (for example, a bank structure) and the third planarization layer 213 may be located on the first capping layer CAP1.

The partition wall BWL may surround the emission area where the light emitting elements LE of each sub-pixel SPX (for example, the first light emitting element LE1 and the second light emitting element LE2 of each sub-pixel SPX) are located. For example, the partition wall BWL may surround the light emitting elements LE of each sub-pixel SPX at a position spaced apart from the light emitting elements LE. The partition wall BWL may define a light transmitting area, for example, the emission area of each sub-pixel SPX, through which light emitted from the light emitting elements LE may transmit. For example, the partition wall BWL may be located around the periphery of the emission area to surround each emission area including the area where the light emitting elements LE of each sub-pixel SPX are located and the periphery thereof, and may be opened to correspond to the emission area.

The partition wall BWL may include a bank BNK defining the shape of the partition wall BWL and a first inorganic film IOL1 covering the bank BNK. In one or more embodiments, the partition wall BWL may further include the reflective film RF located on the first inorganic film IOL1, and a second inorganic film IOL2 covering the reflective film RF.

The bank BNK may include an organic material. For example, the bank BNK may be formed as an organic film including an organic material such as acrylic resin, epoxy resin, phenolic resin, polyamide resin, and/or polyimide resin, but the present disclosure is not limited thereto.

In one or more embodiments, the bank BNK may include a light blocking material. For example, the bank BNK may include a black or colored (for example, purple) pigment and/or dye capable of blocking or reducing the transmission of light emitted from the light emitting elements LE.

In one or more embodiments, the bank BNK may overlap the electrode lines ELI, and may fill a groove formed in a portion where the insulating layer IL is removed (for example, a portion including a portion where the electrode lines ELI and the electrode patterns EPT of the common electrode CE are in contact with each other). In this case, the bank BNK may prevent or reduce lateral light leakage between adjacent sub-pixels SPX, which is advantageous in improving image quality.

The first inorganic film IOL1 may include an inorganic material. For example, the first inorganic film IOL1 may include an inorganic material such as silicon nitride (SiNₓ, e.g., Si₃N₄), silicon oxynitride (SiOₓN_{y}), silicon oxide (SiOₓ, e.g., SiO₂), titanium oxide (TiOₓ, e.g., TiO₂), and/or aluminum oxide (AlOₓ, e.g., Al₂O₃).

The reflective film RF may be located on the side surface of the bank BNK. In one or more embodiments, the reflective film RF may be located also on the top surface of the bank BNK. For example, the reflective film RF may entirely cover the bank BNK.

The reflective film RF may face the side surface of the light emitting element LE. The case where the reflective film RF faces the side surface of the light emitting element LE includes the case where the reflective film RF horizontally faces at least a part of the side surface of the light emitting element LE at the same height, and may also include the case where the reflective film RF is located at a position and/or height where the light emitted from the light emitting element LE in the lateral direction may reach.

The reflective film RF may include a material having suitably high light reflectivity, for example, a metal such as aluminum (Al). In one or more embodiments, the reflective film RF may be formed as a distributed Bragg reflector including inorganic films (for example, silicon nitride (SiNₓ, e.g., Si₃N₄), silicon oxynitride (SiOₓN_{y}), silicon oxide (SiOₓ, e.g., SiO₂), titanium oxide (TiOₓ, e.g., TiO₂), and/or aluminum oxide (AlOₓ, e.g., Al₂O₃)) that have different refractive indices and are arranged alternately with each other. The light transmitted in the lateral direction of the light emitting element LE may be reflected by the reflective film RF, thereby increasing the light emission ratio of the sub-pixel SPX.

The second inorganic film IOL2 may include an inorganic material. For example, the second inorganic film IOL2 may include an inorganic material such as silicon nitride (SiNₓ, e.g., Si₃N₄), silicon oxynitride (SiOₓN_{y}), silicon oxide (SiOₓ, e.g., SiO₂), titanium oxide (TiOₓ, e.g., TiO₂), and/or aluminum oxide (AlOₓ, e.g., Al₂O₃). In some embodiments, the second inorganic film IOL2 may not be provided.

The third planarization layer 213 may be filled between the light emitting elements LE and the partition wall BWL. In one or more embodiments, the third planarization layer 213 may be formed to have a height higher than the height of the light emitting elements LE and the partition wall BWL, thereby entirely covering the light emitting elements LE and the partition wall BWL.

The third planarization layer 213 may include an organic material. For example, the third planarization layer 213 may be formed as an organic film including an organic material such as acrylic resin, epoxy resin, phenolic resin, polyamide resin, polyimide resin, and/or the like. The third planarization layer 213 may alleviate, reduce, or substantially flatten stepped portions caused by the light emitting elements LE and the partition wall BWL. For example, the top surface of the third planarization layer 213 may be substantially flat.

In one or more embodiments, the light emitting elements LE may be to emit light of a color corresponding to the emission color of each of the sub-pixels SPX, and the third planarization layer 213 may be to transmit light emitted from the light emitting elements LE of the sub-pixels SPX. For example, the light emitting elements LE of the first sub-pixel SPX1 may be to emit light of the first color (for example, red light), the light emitting elements LE of the second sub-pixel SPX2 may be to emit light of the second color (for example, green light), and the light emitting elements LE of the third sub-pixel SPX3 may be to emit light of the third color (for example, blue light). The light of the first color, the light of the second color, and the light of the third color emitted from the light emitting elements LE of the sub-pixels SPX may transmit through the third planarization layer 213. When the sub-pixels SPX include the light emitting elements LE that emit light corresponding to each emission color, the light emitted from the light emitting elements LE may be utilized more efficiently. For example, it is possible to prevent or reduce a decrease in the light efficiency of the sub-pixels SPX due to light conversion.

In some embodiments, when the light emitting elements LE of at least one sub-pixel SPX are configured to emit light of a color different from the emission color of the corresponding sub-pixel SPX, the light conversion layer may be located on the light emitting elements LE. An embodiment including the light conversion layer will be described in more detail herein below.

The color filters may be located on the third planarization layer 213. The color filters may include a first color filter CF1, a second color filter CF2, and a third color filter CF3.

The first color filter CF1 may be located on the light emitting element LE of the first sub-pixel SPX1. The first color filter CF1 may be to transmit light of the first color (e.g., red light) and absorb, block, or reduce light of other colors (e.g., green light and blue light). Accordingly, the first sub-pixel SPX1 may be to emit light of the first color.

The second color filter CF2 may be located on the light emitting element LE of the second sub-pixel SPX2. The second color filter CF2 may be to transmit light of the second color (e.g., green light) and absorb, block, or reduce light of other colors (e.g., red light and blue light). Accordingly, the second sub-pixel SPX2 may be to emit light of the second color.

The third color filter CF3 may be located on the light emitting element LE of the third sub-pixel SPX3. The third color filter CF3 may be to transmit light of the third color (e.g., blue light) and absorb, block, or reduce light of other colors (e.g., red light and green light). Accordingly, the third sub-pixel SPX3 may be to emit light of the third color.

The first color filter CF1, the second color filter CF2, and the third color filter CF3 may overlap the partition wall BWL in the third direction DR3. For example, the first color filter CF1, the second color filter CF2, and the third color filter CF3 may overlap each other on the partition wall BWL and form a light blocking pattern.

A fourth planarization layer 214 (for example, an organic insulating layer or an overcoat layer) may be located on the color filters. In one or more embodiments, the fourth planarization layer 214 may be formed as an organic film including acrylic resin, epoxy resin, phenolic resin, polyamide resin, polyimide resin, and/or the like. The fourth planarization layer 214 may alleviate, reduce, or substantially flatten the stepped portion caused by the first color filter CF1, the second color filter CF2, and the third color filter CF3. For example, the top surface of the fourth planarization layer 214 may be substantially flat. The fourth planarization layer 214 may protect the color filters, and assist in substantially uniform transmission of light.

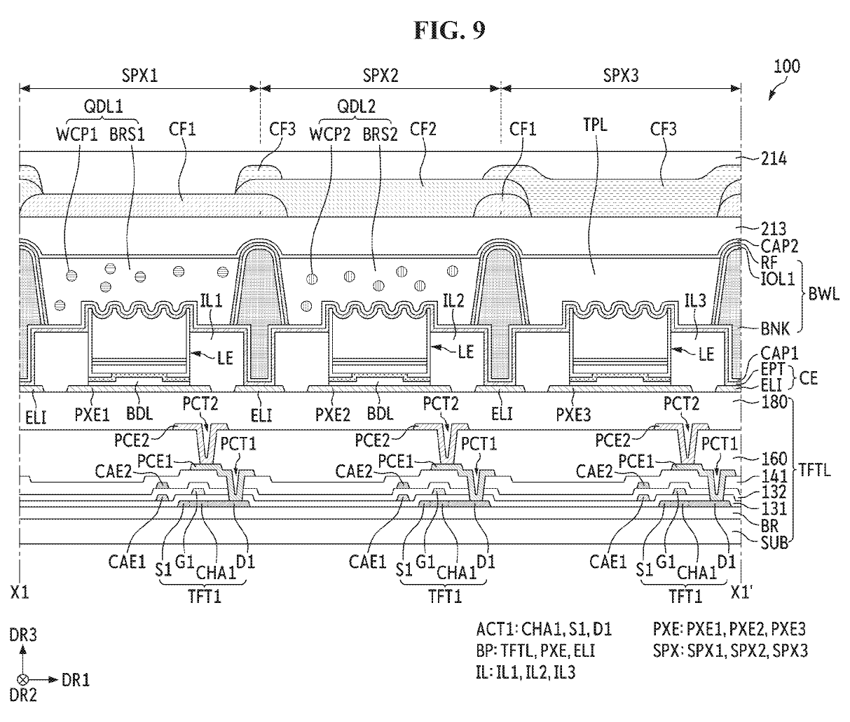

FIG. 9 is a cross-sectional view illustrating a display area of a display panel according to one or more embodiments. For example, FIG. 9 illustrates one or more embodiments of a cross-section of the pixel PX corresponding to line X1-X1' of FIG. 5. Compared to FIG. 7, FIG. 9 illustrates one or more embodiments in which the display panel 100 further includes a light conversion layer. In describing the following embodiments, elements similar or substantially identical to those of at least one or more embodiments described above are designated with the same reference numerals, and redundant descriptions will not be provided.

Referring to FIG. 9, the partition wall BWL, a first light conversion layer QDL1, a second light conversion layer QDL2, a light transmitting layer TPL, a second capping layer CAP2, and the third planarization layer 213 may be located on the first capping layer CAP1.

The partition wall BWL may be located on the first capping layer CAP1, and may surround the light emitting elements LE, the first light conversion layer QDL1, the second light conversion layer QDL2, and the light transmitting layer TPL. The partition wall BWL may define the respective light transmitting areas where the first light conversion layer QDL1, the second light conversion layer QDL2, and the light transmitting layer TPL are located. For example, the partition wall BWL may define or partition a space where the first light conversion layer QDL1, the second light conversion layer QDL2, and the light transmitting layer TPL may be located, and may be formed to have a height that is appropriate or suitable for securing the dimension (for example, height and/or volume) of the space. The height of the partition wall BWL may be similar to or the same as the height of the first light conversion layer QDL1, the second light conversion layer QDL2, and the light transmitting layer TPL. In one or more embodiments, the partition wall BWL may include the bank BNK, the first inorganic film IOL1, and the reflective film RF. The partition wall BWL may or may not include (e.g., may exclude) the second inorganic film IOL2 of FIG. 7. For example, the partition wall BWL may not include (e.g., may exclude) the second inorganic film IOL2, and may be covered by the second capping layer CAP2.

The first light conversion layer QDL1 may be located on the light emitting elements LE of the first sub-pixel SPX1. In one or more embodiments, the light emitting elements LE of the first sub-pixel SPX1 may be to emit light of the third color (for example, blue light), and the first light conversion layer QDL1 may convert part of the light of the third color incident from the light emitting elements LE of the first sub-pixel SPX1 into light of the first color (for example, red light).

The first light conversion layer QDL1 may include a first base resin BRS1 and a first wavelength conversion particle WCP1. The first base resin BRS1 may include a light-transmissive organic material. The first wavelength conversion particle WCP1 may convert part of light of the third color incident from the light emitting elements LE of the first sub-pixel SPX1 into light of the first color. The first wavelength conversion particle WCP1 may be a quantum dot, a quantum rod, a fluorescent material, and/or a phosphorescent material. In one or more embodiments, the first light conversion layer QDL1 may further include light scatterers (e.g., particles capable of scattering and/or diffusing light, such as titanium dioxide (TiO₂) and/or silicon dioxide (SiO₂)).

The second light conversion layer QDL2 may be located on the light emitting elements LE of the second sub-pixel SPX2. In one or more embodiments, the light emitting elements LE of the second sub-pixel SPX2 may be to emit light of the third color, and the second light conversion layer QDL2 may convert part of the light of the third color incident from the light emitting elements LE of the second sub-pixel SPX2 into light of the second color (for example, green light).

The second light conversion layer QDL2 may include a second base resin BRS2 and a second wavelength conversion particle WCP2. The second base resin BRS2 may contain a light-transmissive organic material. The second wavelength conversion particle WCP2 may convert part of the light of the third color incident from the light emitting elements LE of the second sub-pixel SPX2 into light of the second color. The second wavelength conversion particle WCP2 may be a quantum dot, a quantum rod, a fluorescent material, and/or a phosphorescent material. In one or more embodiments, the second light conversion layer QDL2 may further include a light scatterer.

The light transmitting layer TPL may be located on the light emitting element LE of the third sub-pixel SPX3. In one or more embodiments, the light emitting elements LE of the third sub-pixel SPX3 may be to emit light of the third color, and the light transmitting layer TPL may directly transmit the light of the third color incident from the light emitting elements LE of the third sub-pixel SPX3.

The light transmitting layer TPL may include a light-transmissive organic material. In one or more embodiments, the light transmitting layer TPL may further include a light scatterer. When the first sub-pixel SPX1, the second sub-pixel SPX2, and the third sub-pixel SPX3 of the pixel PX include the light emitting elements LE that emit light of the same color, the manufacturing efficiency of the display panel 100 may be increased.

The second capping layer CAP2 may be located on the partition wall BWL, the first light conversion layer QDL1, the second light conversion layer QDL2, and the light transmitting layer TPL. The second capping layer CAP2 may include an inorganic material suitable for encapsulating the first light conversion layer QDL1, the second light conversion layer QDL2, and the light transmitting layer TPL. For example, the first capping layer CAP1 may be formed as an inorganic film including an inorganic insulating material such as silicon nitride (SiNₓ, e.g., Si₃N₄), silicon oxynitride (SiOₓN_{y}), silicon oxide (SiOₓ, e.g., SiO₂), titanium oxide (TiOₓ, TiO₂), and/or aluminum oxide (AlOₓ, e.g., Al₂O₃).

The third planarization layer 213 may be located on the second capping layer CAP2. Color filters (e.g., the first, second, and third color filters CF1, CF2, and CF3) and the fourth planarization layer 214 may be located on the third planarization layer 213.

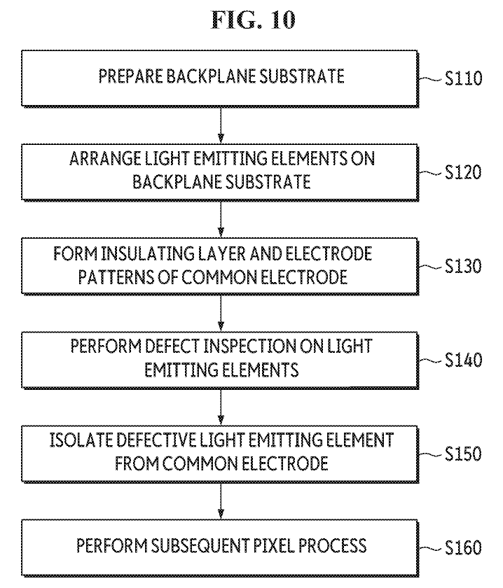

FIG. 10 is a flowchart illustrating a method for manufacturing the display device according to one or more embodiments. For example, FIG. 10 is a flowchart schematically showing a method for manufacturing the display panel 100 included in the display device 1 according to one or more embodiments, and schematically shows a method for manufacturing the display panel 100, including performing defect inspection on the light emitting elements LE to detect a defective light emitting element that may emit light abnormally, and repairing the defect of the sub-pixel SPX due to the defective light emitting element.

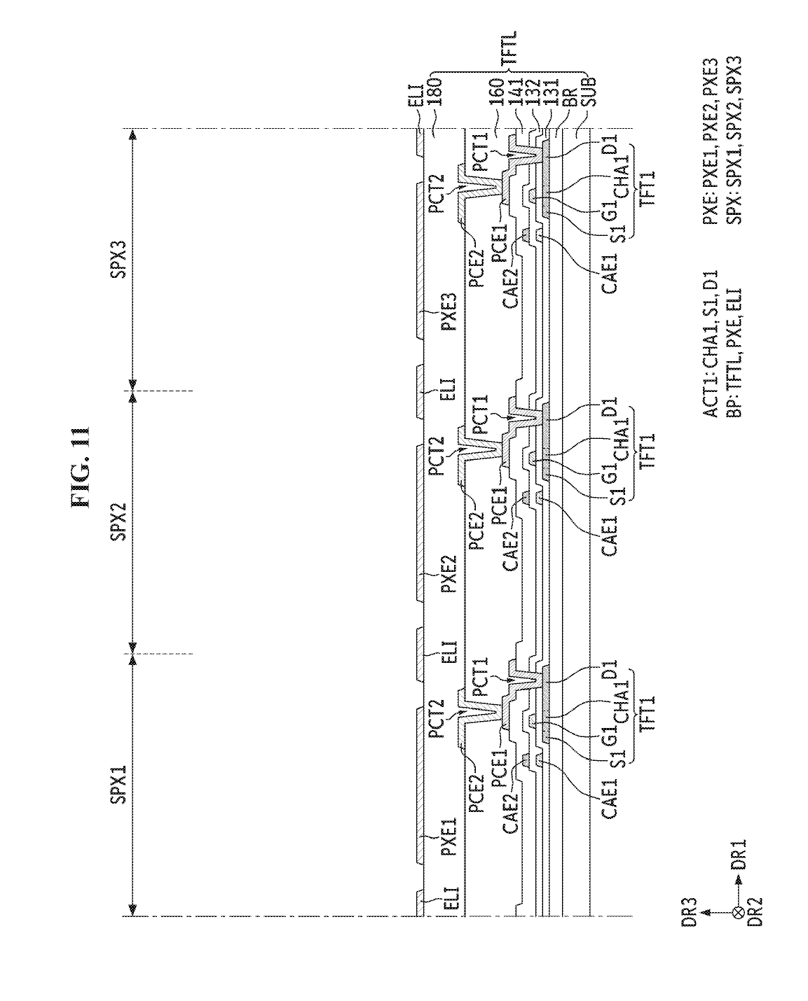

FIGS. 11 to 16 are cross-sectional views illustrating a method for manufacturing the display device according to one or more embodiments. For example, FIGS. 11 to 16 sequentially show manufacturing steps (or acts) for forming a light emitting element layer including the light emitting elements LE among the manufacturing steps (or acts) of the display device 1 including the display panel 100 according to the embodiment of FIG. 7. In one or more embodiments, FIGS. 11 to 16 show a method for manufacturing a display device, including repairing the defect of the sub-pixel SPX due to a defective light emitting element LEd. The display panel 100 according to the embodiment of FIG. 9 may be manufactured in a manner that is substantially the same as or similar to that of the display panel 100 according to the embodiment of FIG. 7, except that a step (e.g., act or task) of forming the first light conversion layer QDL1, the second light conversion layer QDL2, the light transmitting layer TPL, and the second capping layer CAP2 on the first capping layer CAP1 is further included.

Referring to FIGS. 10 and 11 in addition to FIGS. 5 to 9, first, the backplane substrate BP may be prepared in order to manufacture the display panel 100 of the display device 1 according to one or more embodiments (S110).

For example, the thin film transistor TFT1 and/or the like may be formed on the substrate SUB to form the thin film transistor layer TFTL, and the pixel electrodes PXE and the electrode lines ELI may be formed on the thin film transistor layer TFTL. For example, after a single-layer or multi-layer conductive film including a low-resistance metal is formed on the thin film transistor layer TFTL, the conductive film may be etched to form the pixel electrodes PXE and the electrode lines ELI.

The pixel electrodes PXE and the electrode lines ELI may be formed separately from each other. For example, the pixel electrodes PXE may be formed separately from each other at positions corresponding to the emission areas of the sub-pixels SPX, and the electrode lines ELI may be formed to be spaced apart from the pixel electrodes PXE between the pixel electrodes PXE and/or around the pixel electrodes PXE (for example, on respective sides of each pixel electrode PXE).

Accordingly, the backplane substrate BP including the thin film transistor layer TFTL, the pixel electrodes PXE, and the electrode lines ELI may be prepared. For example, the backplane substrate BP may be formed by the above-described process.

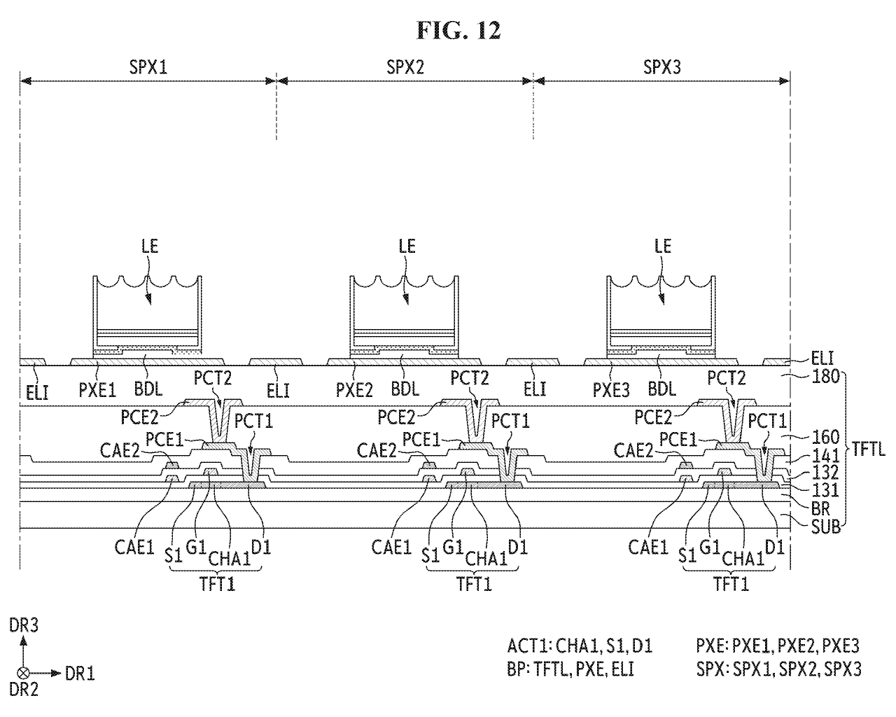

Referring to FIGS. 10 and 12, the light emitting elements LE may be located on the backplane substrate BP (S120).

For example, the plurality of light emitting elements LE (for example, the first light emitting element LE1 and the second light emitting element LE2 of FIGS. 5 or 6) may be located on the pixel electrode PXE of each of the sub-pixels SPX. In one or more embodiments, the bonding layer BDL may be formed between the pixel electrodes PXE and the light emitting elements LE, and the light emitting elements LE may be bonded onto the pixel electrodes PXE via the bonding layer BDL, but the arrangement type or kind (for example, the bonding type or kind) of the light emitting element LE is not limited thereto.

Referring to FIGS. 10, 13, and 14, the insulating layer IL, and the electrode patterns EPT of the common electrode CE may be formed (step(e.g., act or task) S130).

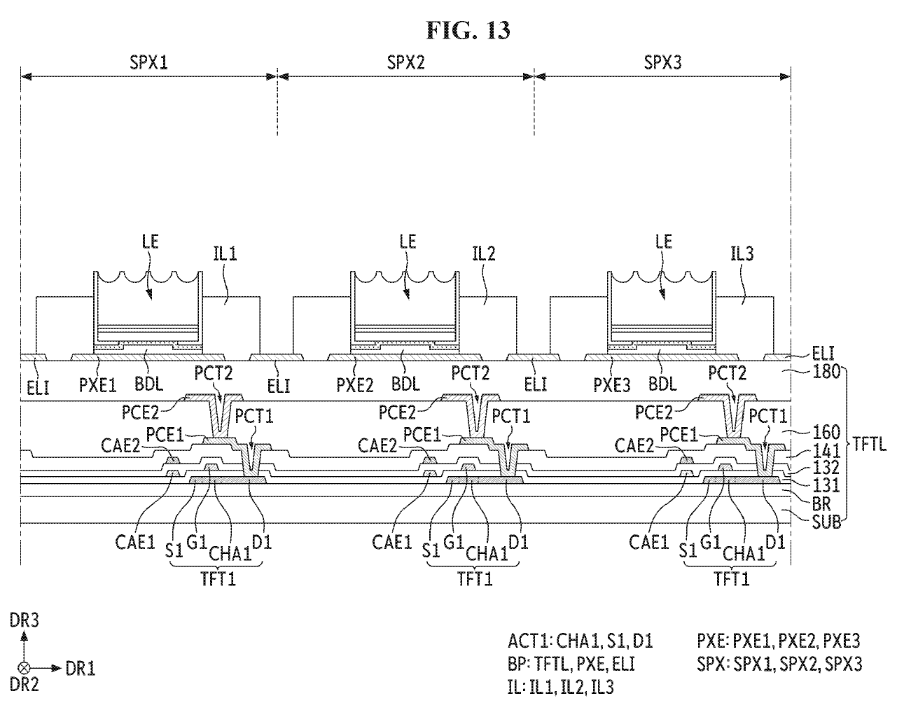

For example, as illustrated in FIG. 13, the insulating layer IL may be formed around the light emitting elements LE. The insulating layer IL may surround the light emitting elements LE. For example, the insulating layer IL may be formed on the thin film transistor layer TFTL to have a height lower than the height of the light emitting elements LE, thereby covering a part of the side surfaces of the light emitting elements LE. In one or more embodiments, the insulating layer IL may be formed to have a height higher than the height of the light emitting elements LE to entirely cover the side surfaces of the light emitting elements LE. In one or more embodiments, the insulating layer IL may cover a part of the pixel electrodes PXE and/or the electrode lines ELI.

The insulating layer IL may be opened and/or divided to expose at least a part of the electrode lines ELI. For example, the insulating layer IL may include a plurality of insulating patterns, including the first insulating pattern IL1 that partially (or entirely) covers the side surfaces of the light emitting elements LE included in at least one first sub-pixel SPX1, the second insulating pattern IL2 that partially (or entirely) covers the side surfaces of the light emitting elements LE included in at least one second sub-pixel SPX2, and the third insulating pattern IL3 that partially (or entirely) covers the side surfaces of the light emitting elements LE included in at least one third sub-pixel SPX3. In one or more embodiments, a part of the electrode lines ELI may be exposed between the plurality of insulating patterns. In some embodiments, the insulating layer IL may be located in the entire display area DA, and the connection holes that expose a part of the electrode lines ELI may be formed in the insulating layer IL. For example, the insulating layer IL may be locally opened and/or removed at portions where the connection holes are formed.

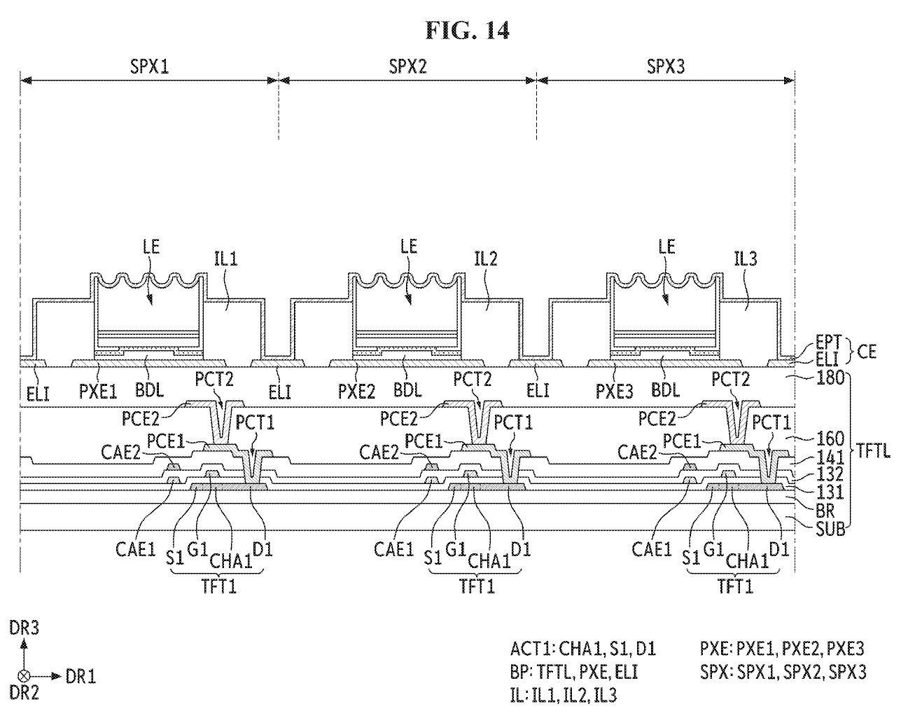

Thereafter, the electrode patterns EPT may be formed on the electrode lines ELI, the light emitting elements LE, and the insulating layer IL as illustrated in FIG. 14. The electrode patterns EPT may include a transparent conductive material and may be formed to intersect the electrode lines ELI. For example, after a transparent conductive film including a transparent conductive material such as indium-tin oxide (ITO) and/or indium-zinc oxide (IZO) is formed on the electrode lines ELI, the light emitting elements LE, and the insulating layer IL, the transparent conductive film may be etched to form the electrode patterns EPT. As illustrated in FIG. 5 or FIG. 6, the electrode patterns EPT according to one or more embodiments may have a relatively wide first width W1 at the first portions EPT1 covering the respective light emitting elements LE, and a relatively narrow second width W2 at the second portions EPT2 that connect the first portions EPT1 to each other.

At the portions where the electrode lines ELI and the electrode patterns EPT intersect, the electrode lines ELI may be located on the exposed portions of the electrode lines ELI to be in contact with the electrode lines ELI. Accordingly, the electrode lines ELI and the electrode patterns EPT may be electrically connected to each other, thereby forming the mesh-shaped common electrode CE.

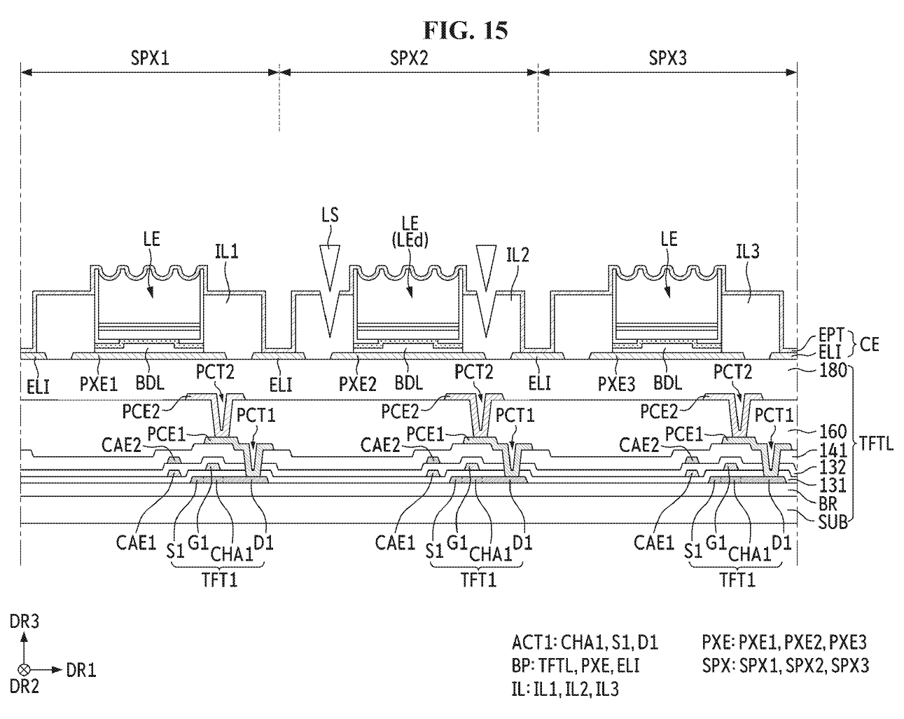

Referring to FIGS. 10 and 15, the defect inspection for the light emitting elements LE may be performed, and the defective light emitting element LEd may be isolated from the common electrode CE if the defective light emitting element LEd is detected (S140 and S150).

For example, after the common electrode CE is formed, before the first capping layer CAP1 of FIG. 7 is formed, the defect inspection including electroluminescence (EL) inspection and/or photoluminescence (PL) inspection may be performed. The EL inspection may be inspection in which a driving voltage is applied to the pixel electrodes PXE and the common electrode CE, and the emission characteristics of the light emitting elements LE are checked. The PL inspection may be inspection in which the emission characteristics are checked by irradiating an external light source to at least one light emitting element LE (for example, the light emitting element LE that emits light abnormally in the EL inspection). The defective light emitting element LEd that emits light abnormally (for example, not turned on) may be detected by the defect inspection.

If the defective light emitting element LEd is detected, the defective light emitting element LEd may be electrically isolated. For example, the defective light emitting element LEd may be isolated (for example, electrically isolated) from the common electrode CE. For example, as shown in FIG. 15, if one light emitting element LE included in one second sub-pixel SPX2 is the defective light emitting element LEd, a part of the electrode pattern EPT (for example, the second portions EPT2 of the electrode pattern EPT located on respective sides of the defective light emitting element LEd) may be disconnected around the defective light emitting element LEd using a laser LS. In this process, a part of the insulating layer IL (for example, a part of the second insulating pattern IL2 located on respective sides of the defective light emitting element LEd) under the disconnected portion of the electrode pattern EPT may also be removed.

In one or more embodiments, after the defective light emitting element LEd is isolated from the common electrode CE, additional EL inspection may be performed to check whether the light emitting elements LE of the sub-pixels SPX emit light normally. If another light emitting element LE located in the second sub-pixel SPX2 including the defective light emitting element LEd is a normal light emitting element that may emit light normally, the normal light emitting element may be to emit light with a luminance corresponding to the driving current Ids flowing in the second sub-pixel SPX2. Accordingly, the defect of the sub-pixel SPX (for example, the second sub-pixel SPX2 including the defective light emitting element LEd and the normal light emitting element LE) due to the defective light emitting element LEd may be repaired. If the defective light emitting element LEd is not detected, the repair process may not be performed.

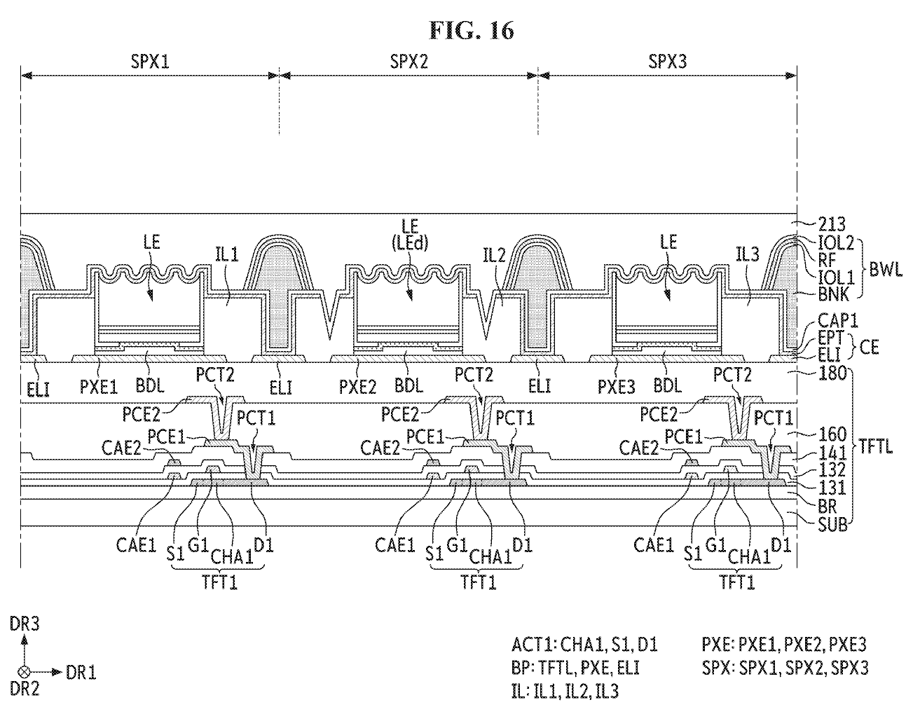

Referring to FIGS. 10 and 16, a subsequent pixel process may be performed (S160).

For example, the first capping layer CAP1, the partition wall BWL, and the third planarization layer 213 may be formed on the light emitting elements LE and the common electrode CE.

By the process described with reference to FIGS. 10 to 16, the light emitting element layer including the pixel electrodes PXE, the light emitting elements LE, the insulating layer IL, and the common electrode CE may be formed on the backplane substrate BP.

In one or more embodiments, when the display panel 100 further includes the first, second, and third color filters CF1, CF2, and CF3 and the fourth planarization layer 214 of FIG. 7, the first, second, and third color filters CF1, CF2, and CF3 and the fourth planarization layer 214 may be formed on the third planarization layer 213. Accordingly, the display panel 100 according to one or more embodiments may be formed.

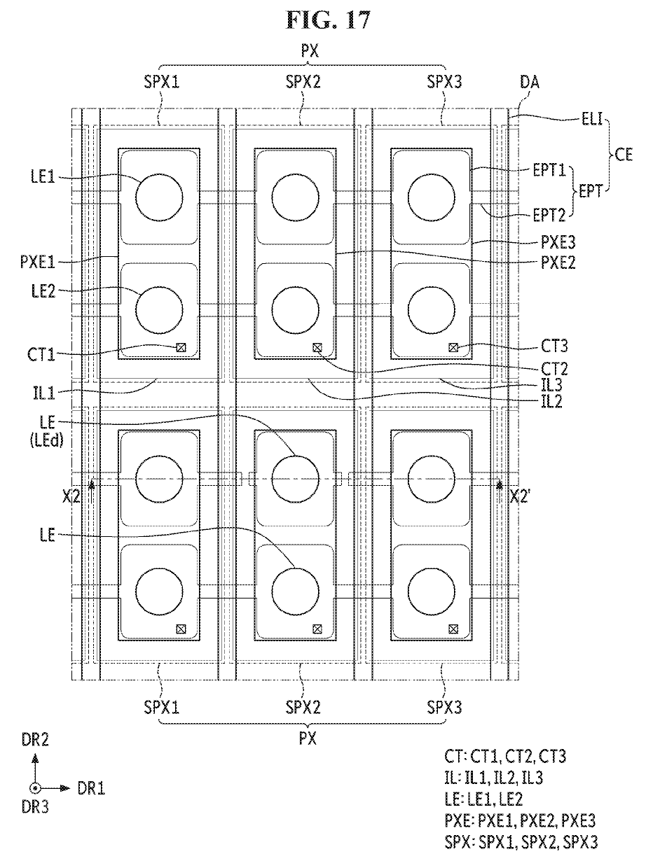

FIG. 17 is a plan view illustrating a display area of a display panel according to one or more embodiments. For example, FIG. 17 shows a part of the display area DA including two pixels PX sequentially arranged in the second direction DR2. Compared to FIG. 5, FIG. 17 shows a part of the display area DA where the sub-pixel SPX including the defective light emitting element LEd is located.

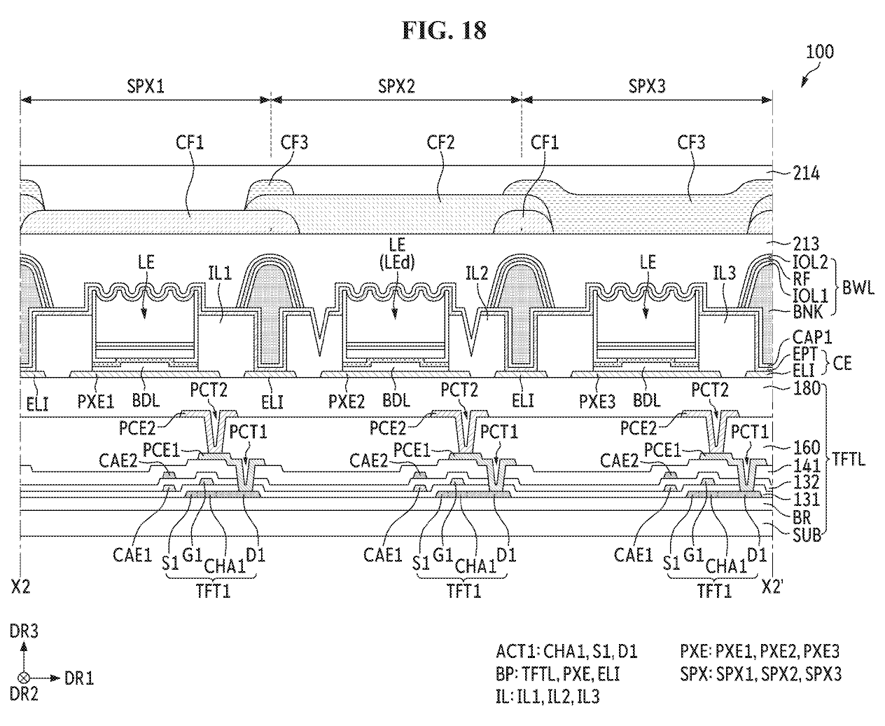

FIG. 18 is a cross-sectional view illustrating a display area of a display panel according to one or more embodiments. For example, FIG. 18 shows an example of the cross-section of the pixel PX corresponding to line X2-X2' of FIG. 17.

Referring to FIGS. 17 and 18 in addition to FIGS. 1 to 16, the display panel 100 according to one or more embodiments may include the sub-pixels SPX located in the display area DA. In one or more embodiments, at least one sub-pixel SPX among the sub-pixels SPX may include the defective light emitting element LEd (for example, the first light emitting element LE1 of the at least one sub-pixel SPX) and the light emitting element LE that emits light normally (for example, the second light emitting element LE2 of the at least one sub-pixel SPX), and the other sub-pixels SPX may include the light emitting elements LE that emit light normally.

In the sub-pixel SPX including the defective light emitting element LEd, the electrode pattern EPT may be disconnected around the defective light emitting element LEd. For example, the electrode pattern EPT located on the defective light emitting element LEd may be disconnected at the second portions EPT2 located around the defective light emitting element LEd and isolated from the common electrode CE by the repair process performed after the detection of the defective light emitting element LEd. The other light emitting element LE (normal light emitting element) included in the sub-pixel SPX including the defective light emitting element LEd may be electrically connected between the pixel electrode PXE and the common electrode CE, and thus may be to emit light with a luminance corresponding to the driving current Ids flowing in the corresponding sub-pixel SPX.

As described above, the display device 1 according to one or more embodiments may include the mesh-shaped common electrode CE including the electrode lines ELI and the electrode patterns EPT. The electrode lines ELI and the electrode patterns EPT may extend in different directions and intersect each other. For example, the electrode lines ELI may be formed as vertical patterns respectively extending in the second direction DR2, and the electrode patterns EPT may be formed as horizontal patterns respectively extending in the first direction DR1.

In one or more embodiments, the electrode lines ELI of the common electrode CE may include a low-resistance conductive material. For example, by forming the patterns of the pixel electrode layer including the pixel electrodes PXE and the electrode lines ELI using a metal having a suitably low resistivity (or a metal film having a suitably low sheet resistance), the resistance of the common electrode CE may be reduced. Accordingly, the voltage drop (IR drop) of the second driving voltage VSS applied to the light emitting elements LE through the common electrode CE may be reduced, and the image quality of the display device 1 may be improved.

In the embodiments, the electrode patterns EPT of the common electrode CE may be formed on the light emitting elements LE, and may serve as bridges that connect the electrode lines ELI. The electrode patterns EPT may be formed using a transparent conductive material. Accordingly, light generated from the light emitting elements LE may transmit through the electrode patterns EPT and be emitted to the upper sides of the sub-pixels SPX.

In some embodiments, because the resistance of the common electrode CE is reduced by the electrode lines ELI, the thickness of the electrode patterns EPT may be reduced. For example, in the case of forming the mesh-shaped common electrode CE including the electrode lines ELI and the electrode patterns EPT, compared to the case of forming the common electrode CE as a common layer including the same transparent electrode material as the electrode patterns EPT and located in the entire display area DA, the resistance of the common electrode CE may be reduced even if the electrode patterns EPT are formed to have a thickness less than the thickness of the common electrode CE formed as the common layer. For example, the electrode patterns EPT may be formed to have a thickness less than 1000 Å. Accordingly, the electrode patterns EPT may be formed more uniformly (e.g., substantially uniformly) and the risk of residue may be reduced, thereby improving the yield of the display device 1.

In some embodiments, each sub-pixel SPX may include the plurality of light emitting elements LE located on each pixel electrode PXE. Accordingly, the defect (for example, abnormal emission and/or dark spot) of the sub-pixel SPX due to the defective light emitting element LEd may be easily identified and repaired. For example, if the defective light emitting element LEd is detected among the plurality of light emitting elements LE included in one sub-pixel SPX, the defective light emitting element LEd may be electrically isolated and turned off, and another light emitting element LE that is normal (e.g., functioning properly) may be used as a light source to enable the sub-pixel SPX to emit light. Accordingly, the defect of the sub-pixel SPX due to the defective light emitting element LEd may be easily repaired without replacing the defective light emitting element LEd. Accordingly, the manufacturing cost of the display device 1 may be reduced, and the manufacturing efficiency may be increased.

In some embodiments, each of the electrode patterns EPT of the common electrode CE may include the first portions EPT1 that cover the upper portions of the respective light emitting elements LE, and the second portions EPT2 that connect the first portions EPT1 and have a relatively narrow width. For example, the electrode patterns EPT may be formed as bottleneck-shaped patterns having a relatively narrow width at the second portions EPT2 that do not overlap the light emitting elements LE. Accordingly, if the defective light emitting element LEd is detected in the defect inspection performed after the light emitting elements LE are placed on the pixel electrodes PXE, the defective light emitting element LEd and the common electrode CE may be easily separated by disconnecting the second portions EPT2 of the electrode pattern EPT around the defective light emitting element LEd. Accordingly, it is possible to more easily repair the defect of the sub-pixel SPX caused by the defective light emitting element LEd, and further increase the manufacturing efficiency of the display device 1.

The display device 1 according to at least one of the above-described embodiments may be applied to one or more suitable electronic devices. The electronic device according to one or more embodiments may include the above-described display device 1 (or a display module including the display panel 100 according to at least one or more embodiments), and may further include modules and/or devices having other additional functions, in addition to the display device 1.

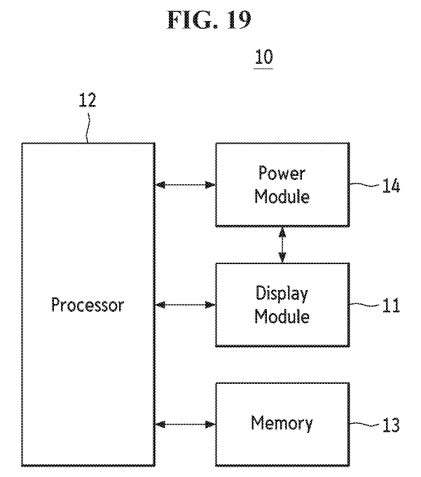

FIG. 19 is a block diagram of an electronic device according to one or more embodiments.

Referring to FIG. 19, an electronic device 10 according to one or more embodiments may include a display module 11, a processor 12, a memory 13, and a power module 14.

The electronic device 10 may output various information in the form of images through the display module 11. For example, when the processor 12 executes an application stored in the memory 13, image information provided by the application may be provided to a user through the display module 11.

The display module 11 may include the display panel 100 for displaying an image. For example, the display module 11 may include the display panel 100 according to at least one of the aforementioned embodiments.

The processor 12 may include at least one selected from among a central processing unit (CPU), an application processor (AP), a graphic processing unit (GPU), a communication processor (CP), an image signal processor (ISP), and a controller.

The memory 13 may store data information desired or required for the operation of the processor 12 and/or the display module 11. For example, the memory 13 may store an image data signal (for example, the digital video data DATA transmitted to the timing controller 251 of FIG. 3) and/or an input control signal.

The processor 12 may control the display module 11 using information stored in the memory 13. The processor 12 may be to transmit the image data signal and/or the input control signal stored in the memory 13 to the display module 11. For example, when the processor 12 executes an application stored in the memory 13, an image data signal and/or an input control signal is transmitted to the display module 11, and the display module 11 may process the received signal and output image information through a display screen.

The power module 14 may include a power supply module, such as a power adapter and/or a battery device, and a power conversion module that converts power supplied by the power supply module to generate power desired or required for the operation of the electronic device 10.

At least one of the components of the electronic device 10 described above may be included in the display device 1 according to the embodiments described above. Further, some of individual modules functionally included in one module may be included in the display device 1 and some others may be provided separately from the display device 1. For example, the display device 1 may include the display module 11, and the processor 12, the memory 13, and the power module 14 may be provided in the form of other devices in the electronic device 10 other than the display device 1.

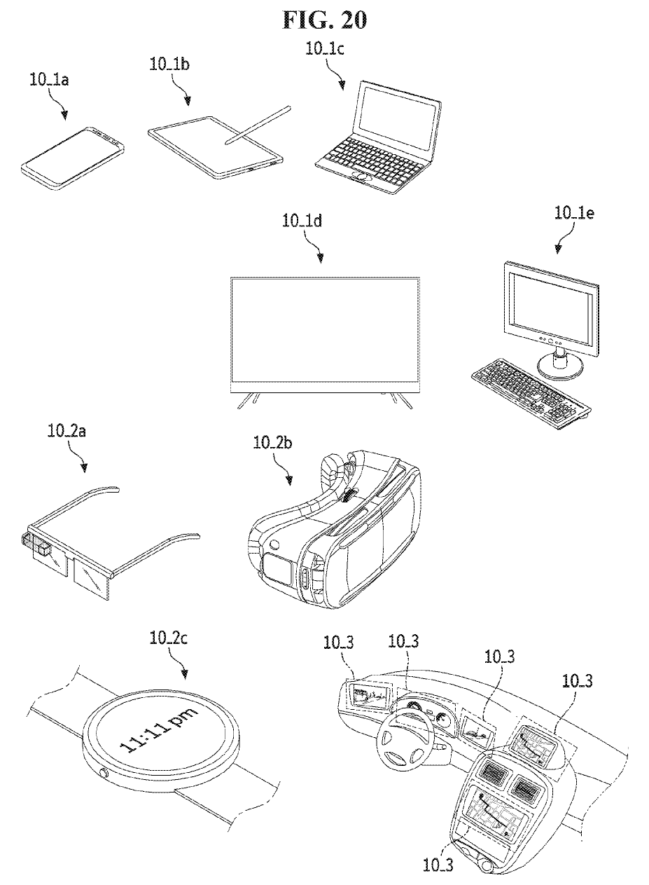

FIG. 20 is schematic views of electronic devices according to one or more embodiments.

Referring to FIG. 20, one or more electronic devices to which the display device 1 according to one or more embodiments is applied may include not only an image display electronic device such as a smartphone 10_1a, a tablet PC 10_1b, a laptop 10_1c, a TV 10_1d, and/or a desk monitor 10_1e, but also a wearable electronic device including a display module, such as smart glasses 10_2a, a head mounted display 10_2b, and/or a smart watch 10_2c, as well as a vehicle electronic device 10_3 including a display module, such as a center fascia, a dashboard of an automobile, a center information display (CID) placed on the dashboard, a room mirror display, and/or the like.

In concluding the detailed description, those skilled in the art will appreciate that many variations and modifications can be made to the embodiments without substantially departing from the principles of the present disclosure. Therefore, the disclosed embodiments of the disclosure are used in a generic and descriptive sense only and not for purposes of limitation, and various modifications to the disclosed embodiments, as well as other example embodiments, are intended to be included within the spirit and scope of the present disclosure as defined in the appended claims, and their equivalents.

What is claimed is:

1. A display device comprising:
a substrate;
pixel electrodes and electrode lines spaced apart from each other on the substrate;
light emitting elements on the pixel electrodes; and
electrode patterns on the light emitting elements and intersecting the electrode lines,
wherein the electrode lines and the electrode patterns extend in different directions and are electrically connected to each other to form a mesh-shaped common electrode.

2. The display device of claim 1, wherein the electrode patterns contain a transparent conductive material, and
the electrode lines contain a conductive material having a lower resistivity than the transparent conductive material of the electrode patterns.

3. The display device of claim 2, wherein the pixel electrodes and the electrode lines are located in a same layer and contain a same material.

4. The display device of claim 1, wherein the electrode patterns each extend in a first direction and are arranged in a second direction crossing the first direction.

5. The display device of claim 4, wherein each of the electrode patterns overlaps a plurality of light emitting elements arranged in the first direction among the light emitting elements, and comprises first portions respectively covering the plurality of light emitting elements and second portions connecting the first portions, and
a width of the second portions is less than a width of the first portions.

6. The display device of claim 4, wherein a plurality of light emitting elements among the light emitting elements are on each of the pixel electrodes, and
among the plurality of light emitting elements on one of the pixel electrodes, a first light emitting element is isolated from the mesh-shaped common electrode, and a second light emitting element is electrically connected to the mesh-shaped common electrode.

7. The display device of claim 6, wherein the electrode pattern on the first light emitting element is disconnected at second portions located around the first light emitting element and isolated from the mesh-shaped common electrode.

8. The display device of claim 4, wherein the electrode lines each extend in the second direction and are arranged in the first direction.

9. The display device of claim 8, wherein the pixel electrodes are arranged in the first direction and the second direction, and
the pixel electrodes and the electrode lines are arranged alternately with each other in the first direction.

10. The display device of claim 1, wherein each of the light emitting elements comprises:
a first semiconductor layer on one of the pixel electrodes and electrically connected to the one pixel electrode;
an active layer on the first semiconductor layer; and
a second semiconductor layer on the active layer and electrically connected to the mesh-shaped common electrode.

11. The display device of claim 1, further comprising an insulating layer between the pixel electrodes and the electrode patterns and around the light emitting elements.

12. The display device of claim 11, wherein the insulating layer exposes a part of the electrode lines at a portion where the electrode lines and the electrode patterns intersect each other, and covers another part of the electrode lines, and
at a portion where the electrode lines are exposed, the electrode lines and the electrode patterns are in contact with each other.

13. The display device of claim 11, wherein the insulating layer comprises island-shaped insulating patterns separated from each other and individually located in respective sub-pixels comprising the respective pixel electrodes.

14. The display device of claim 11, wherein the pixel electrodes and the electrode lines are arranged alternately with each other in a first direction, and
the insulating layer comprises insulating patterns separated from each other in the first direction and each extending in a second direction crossing the first direction.

15. The display device of claim 11, further comprising a bank around the light emitting elements at a position spaced apart from the light emitting elements and overlapping the electrode lines,
wherein the bank fills a groove formed in a portion where the insulating layer is removed.

16. An electronic device comprising:
a display module comprising a display panel; and
a processor to transmit an image data signal to the display module,
wherein the display panel comprises:
a substrate;
pixel electrodes and electrode lines spaced apart from each other on the substrate;
light emitting elements on the pixel electrodes; and
electrode patterns on the light emitting elements and intersecting the electrode lines,
wherein the electrode lines and the electrode patterns extend in different directions and are electrically
connected to each other to form a mesh-shaped common electrode.

17. The electronic device of claim 16, wherein the electrode patterns contain a transparent conductive material, and
the electrode lines contain a conductive material having a lower resistivity than the transparent conductive material of the electrode patterns.

18. The electronic device of claim 16, wherein the electrode patterns each extend in a first direction and are arranged in a second direction crossing the first direction, and
each of the electrode patterns overlaps a plurality of light emitting elements arranged in the first direction among the light emitting elements, and comprises first portions respectively covering the plurality of light emitting elements and second portions connecting the first portions and having a width less than a width of the first portions.

19. A method for manufacturing a display device, the method comprising:
preparing a backplane substrate comprising a substrate and pixel electrodes and electrode lines spaced apart from each other on the substrate;
arranging a plurality of light emitting elements on each of the pixel electrodes;
forming an insulating layer around the light emitting elements and exposing a part of the electrode lines;
forming electrode patterns on the electrode lines, the light emitting elements and the insulating layer¸ the electrode patterns intersecting the electrode lines and being electrically connected to the electrode lines; and
performing defect inspection on the light emitting elements,
wherein if a defective light emitting element is detected in the defect inspection, the method further comprises electrically isolating the defective light emitting element.

20. The method of claim 19, wherein each of the electrode patterns extends in a first direction and comprises first portions covering respective light emitting elements arranged in the first direction among the light emitting elements, and second portions connecting the first portions and having a width less than a width of the first portions, and
the electrically isolating of the defective light emitting element comprises disconnecting the second portions of an electrode pattern of the electrode patterns located on the defective light emitting element around the defective light emitting element.
